(19) United States
(12) Patent Application Publication
(10) Pub. No.: US 2024/0402590 A1
(43) Pub. Date: Dec. 5, 2024

(54) PELLICLE, EXPOSURE ORIGINAL PLATE, EXPOSURE DEVICE, AND METHOD OF MANUFACTURING PELLICLE

(71) Applicant: MITSUI CHEMICALS, INC., Chuo-ku, Tokyo (JP)

(72) Inventors: Hirofumi TANAKA, Tsukuba-shi, Ibaraki (JP); Yosuke ONO, Sodegaura-shi, Chiba (JP); Akira ISHIKAWA, Ichihara-shi, Chiba (JP); Yasushi SATOH, Funabashi-shi, Chiba (JP); Hisako ISHIKAWA, Ichihara-shi, Chiba (JP); Masashi FUJIMURA, Ichihara-shi, Chiba (JP); Atsushi OKUBO, Itabashi-ku, Tokyo (JP); Kazuo KOHMURA, Iwakuni-shi, Yamaguchi (JP)

(73) Assignee: MITSUI CHEMICALS, INC., Chuo-ku, Tokyo (JP)

(21) Appl. No.: 18/690,801

(22) PCT Filed: Sep. 12, 2022
(86) PCT No.: PCT/JP2022/034111

§ 371 Date: Mar. 11, 2024

(30) Foreign Application Priority Data
Sep. 13, 2021 (JP) 2021-148629

(51) Int. Cl. G03F 1/62

(52) U.S. Cl. CPC G03F 1/62

(57) ABSTRACT

A pellicle includes an adhesive layer. At least one of an inner wall surface or an outer wall surface of the adhesive layer satisfies Formula (1) below.

$$( [ {A}_{2 s} ] / [ {A}_{50 s} ] ) \leq 0.97 \qquad Formula ( 1 )$$

In Formula (1), A_{2 s} represents a normalized intensity of a partial structure contained in a main agent component obtained by analyzing a first deep portion having a first depth from a surface of the adhesive layer by TOF-SIMS. The first depth is formed by irradiating a 600 μm square area of the surface with a sputter ion gun for a total of 2 seconds. A_{50 s} represents a normalized intensity of a partial structure contained in a main agent component obtained by analyzing a second deep portion where the depth is a second depth by TOF-SIMS. The second depth is formed by irradiating the area with the sputter ion gun for a total of 50 seconds.

### TECHNICAL FIELD

The present disclosure relates to a pellicle, an exposure original plate, an exposure device, and a method of manufacturing a pellicle.

### BACKGROUND ART

There is known a technique (that is, photolithography) in which a photosensitive substance is applied to a surface of an object such as an electronic component, a printed circuit board, or a display panel, and exposed in a pattern shape to form a pattern. In the photolithography, a transparent substrate having a pattern formed on one surface is used. This transparent substrate is called a photomask (Hereinafter, also referred to as “original plate”). A pellicle is attached to the photomask in order to prevent foreign matter such as dust from adhering to the surface of the photomask.

Patent Literature 1 discloses a pellicle. The pellicle disclosed in Patent Literature 1 includes a pellicle film, a pellicle frame, and an adhesive layer. The pellicle film is attached to one end surface of the pellicle frame. The adhesive layer is provided on the other end surface of the pellicle frame. The adhesive layer contains a specific amount of thermally conductive filler.
Patent Literature 1: Japanese Patent Application Laid-Open (JP-A) No. 2011-53603

### SUMMARY OF INVENTION

### Technical Problem

However, when the pellicle as described in Patent Literature 1 is attached to an exposure device and used, there is a possibility that dirt adheres to the pellicle film and the inside of the exposure device. Such contamination is considered to be caused by outgas generated from the adhesive layer.

The present disclosure has been made in view of the above circumstances.

An object of an embodiment of the present disclosure is to provide a pellicle, an exposure original plate, an exposure device, and a method of manufacturing a pellicle, which are less likely to generate outgas.

### Solution to Problem

Means for solving the above problems include the following embodiments.
<1> A pellicle including:
a pellicle frame;
a pellicle film supported on one end surface of the pellicle frame; and
an adhesive layer provided on another end surface of the pellicle frame,
in which at least one of an inner wall surface or an outer wall surface of a surface of the adhesive layer satisfies Formula (1) below.

$$( [ {A}_{2 s} ] / [ {A}_{50 s} ] ) \leq 0.97 \qquad Formula ( 1 )$$

wherein, in Formula (1):
[A_{2 s}] represents a normalized intensity of a partial structure contained in a main agent component of the adhesive layer obtained by analyzing a first deep portion having a first depth from a surface of the adhesive layer by time-of-flight secondary ion mass spectrometry using a primary ion gun in which an ion source is Bi₃⁺⁺ ions and an irradiation region is 100 μm×100 μm,
the first depth is formed by irradiating a 600 μm square area of the surface with a sputter ion gun that is an argon gas cluster ion beam having a beam voltage of 20 kV and a beam current of 20 nA for a total of 2 seconds,
[A_{50 s}] represents a normalized intensity of a partial structure contained in a main agent component of the adhesive layer obtained by analyzing a second deep portion where the depth is a second depth by time-of-flight secondary ion mass spectrometry, and
the second depth is formed by irradiating the area with the sputter ion gun for a total of 50 seconds.
<2> The pellicle according to <1>, in which the partial structure contained in the main agent component is C₃H₃O⁺, C₇H₇⁺, or CH₃Si⁺.
<3> The pellicle according to <1> or <2>, in which the at least one of the inner wall surface or the outer wall surface that satisfies Formula (1) satisfies Formula (2) below.

$$( [ C N {O}_{2 s}^{-} ] / [ CN {O}_{50 s}^{-} ] ) \geq 2.00 \qquad Formula ( 2 )$$

wherein, in Formula (2):
[CNO⁻_{2 s}] represents a normalized intensity of CNO⁻ obtained by analyzing the first deep portion by time-of-flight secondary ion mass spectrometry, and
[CNO⁻_{50 s}] represents a normalized intensity of CNO⁻ obtained by analyzing the second deep portion by time-of-flight secondary ion mass spectrometry.
<4> The pellicle according to any one of <1> to <3>, in which the at least one of the inner wall surface or the outer wall surface that satisfies Formula (1) satisfies Formula (3) below.

$$( [ C {N}_{2 s}^{-} ] / [ {CN}_{50 s}^{-} ] ) \geq 2.00 \qquad Formula ( 3 )$$

wherein, in Formula (3):
[CN⁻_{2 s}] represents a normalized intensity of CN⁻ obtained by analyzing the first deep portion by time-of-flight secondary ion mass spectrometry, and
[CN⁻_{50 s}] represents a normalized intensity of CN⁻ obtained by analyzing the second deep portion by time-of-flight secondary ion mass spectrometry.
<5> The pellicle according to any one of <1> to <4>, in which the at least one of the inner wall surface or the outer wall surface that satisfies Formula (1) satisfies Formula (4) below.

$$( [ C N {O}_{6 s}^{-} ] / [ CN {O}_{50 s}^{-} ] ) \geq 1.5 \qquad Formula ( 4 )$$

wherein, in Formula (4):
[CNO⁻_{6 s}] represents a normalized intensity of CNO⁻ obtained by analyzing a third deep portion having a third depth from the surface of the adhesive layer by time-of-flight secondary ion mass spectrometry using a primary ion gun in which an ion source is Bi₃⁺⁺ ions and an irradiation area is 100 μm×100 μm,
the third depth is formed by irradiating a 600 μm square area of the surface with a sputter ion gun that is an argon gas cluster ion beam having a beam voltage of 20 kV and a beam current of 20 nA for a total of 6 seconds, and
[CNO⁻_{50 s}] represents a normalized intensity of CNO⁻ obtained by analyzing the second deep portion by time-of-flight secondary ion mass spectrometry.
<6> The pellicle according to any one of <1> to <5>, in which the at least one of the inner wall surface or the outer wall surface that satisfies Formula (1) satisfies Formula (5) below.

$$( [ {C}_{{3}^{-} 2 s} ] / [ {C}_{{3}^{-} 50 s} ] ) \geq 1.10 \qquad Formula ( 5 )$$

wherein, in Formula (5):
[C₃⁻_{2 s}] represents a normalized intensity of C₃⁻ obtained by analyzing the first deep portion by time-of-flight secondary ion mass spectrometry, and
[C₃⁻_{50 s}] represents a normalized intensity of C₃⁻ obtained by analyzing the second deep portion by time-of-flight secondary ion mass spectrometry.
<7> The pellicle according to any one of <1> to <6>, in which
a carbon atom concentration of the at least one of the inner wall surface or the outer wall surface is 35 at % or more, and
the carbon atom concentration indicates a ratio (%) of integrated intensity of peak components derived from carbon atoms to integrated intensity of peak components of all components in a narrow spectrum of X-ray photoelectron spectroscopy of the at least one of the inner wall surface or the outer wall surface.
<8> The pellicle according to any one of <1> to <7>, in which
a nitrogen atom concentration of the at least one of the inner wall surface or the outer wall surface is 1.0 at % or more, and
the nitrogen atom concentration indicates a ratio (%) of integrated intensity of peak components derived from nitrogen atoms to integrated intensity of peak components of all components in a narrow spectrum of X-ray photoelectron spectroscopy of the at least one of the inner wall surface or the outer wall surface.
<9> An exposure original plate including: an original plate having a pattern; and the pellicle according to any one of <1> to <8> attached to a surface of the original plate on a side having the pattern.
<10> An exposure device including: a light source that emits exposure light; the exposure original plate according to <9>; and an optical system that guides the exposure light emitted from the light source to the exposure original plate, in which the exposure original plate is disposed such that the exposure light emitted from the light source passes through the pellicle film and is irradiated onto the original plate.
<11> A method of manufacturing the pellicle according to any one of <1> to <8>, the method including:
a step of forming the adhesive layer by subjecting at least one of an inner wall surface or an outer wall surface of a surface of an adhesive layer precursor to a plasma nitriding treatment or an extreme ultraviolet irradiation treatment, the adhesive layer precursor being formed by applying a coating composition to the other end surface of the pellicle frame and heating the coating composition.
<12> The method of manufacturing the pellicle according to <11>, further including:
a step of disposing the pellicle coated with the coating composition under a pressure of 5×10⁻⁴ Pa or less for 10 minutes or more before performing the plasma nitriding treatment, and then disposing the pellicle under an inert gas atmosphere having a partial pressure of H₂O of 100 ppm or less and an atmospheric pressure of 90 kPa or more for 5 seconds or more,
in which the adhesive layer contains an acrylic adhesive.
<13> A pellicle including:
a pellicle frame;
a pellicle film supported on one end surface of the pellicle frame; and
an adhesive layer provided on another end surface of the pellicle frame,
in which at least one of an inner wall surface or an outer wall surface of a surface of the adhesive layer satisfies Formula (2) below.

$$( [ C N {O}_{2 s}^{-} ] / [ CN {O}_{50 s}^{-} ] ) \geq 2.00 \qquad Formula ( 2 )$$

wherein, in Formula (2):
[CNO⁻_{2 s}] represents a normalized intensity of CNO⁻ of the adhesive layer obtained by analyzing a first deep portion having a first depth from a surface of the adhesive layer by time-of-flight secondary ion mass spectrometry using a primary ion gun in which an ion source is Bi₃⁺⁺ ions and an irradiation region is 100 μm×100 μm,
the first depth is formed by irradiating a 600 μm square area of the surface with a sputter ion gun that is an argon gas cluster ion beam having a beam voltage of 20 kV and a beam current of 20 nA for a total of 2 seconds,
[CNO⁻_{50 s}] represents a normalized intensity of CNO⁻ of the adhesive layer obtained by analyzing a second deep portion where the depth is a second depth by time-of-flight secondary ion mass spectrometry, and
the second depth is formed by irradiating the area with the sputter ion gun for a total of 50 seconds.
<14> A pellicle including:
a pellicle frame;
a pellicle film supported on one end surface of the pellicle frame; and
an adhesive layer provided on another end surface of the pellicle frame,
in which at least one of an inner wall surface or an outer wall surface of a surface of the adhesive layer satisfies Formula (5) below.

$$( [ {{{C}_{3}}^{-}}_{2 s} ] / [ {{{C}_{3}}^{-}}_{50 s} ] ) \geq 1.1 \qquad Formula ( 5 )$$

wherein, in Formula (5):
[C₃⁻₂s] represents a normalized intensity of C₃⁻ of the adhesive layer obtained by analyzing a first deep portion having a first depth from a surface of the adhesive layer by time-of-flight secondary ion mass spectrometry using a primary ion gun in which an ion source is Bi₃⁺⁺ ions and an irradiation region is 100 μm×100 μm,
the first depth is formed by irradiating a 600 μm square area of the surface with a sputter ion gun that is an argon gas cluster ion beam having a beam voltage of 20 kV and a beam current of 20 nA for a total of 2 seconds,
[C₃⁻₅₀s] represents a normalized intensity of C₃⁻ of the adhesive layer obtained by analyzing a second deep portion where the depth is a second depth by time-of-flight secondary ion mass spectrometry, and
the second depth is formed by irradiating the area with the sputter ion gun for a total of 50 seconds.

### Advantageous Effects of Invention

According to the present disclosure, there are provided a pellicle, an exposure original plate, an exposure device, and a method of manufacturing a pellicle, which are less likely to generate outgas.

### BRIEF DESCRIPTION OF DRAWINGS

FIG. 1 is a cross-sectional view of a pellicle according to a first embodiment of the present disclosure.

### DESCRIPTION OF EMBODIMENTS

In the present disclosure, a numerical range indicated using “to” means a range including numerical values described before and after “to” as a minimum value and a maximum value, respectively.

In a numerical range described in stages in the present disclosure, an upper limit value or a lower limit value described in a certain numerical range may be replaced with an upper limit value or a lower limit value of another described numerical range in stages. In the numerical range described in the present disclosure, an upper limit value or a lower limit value described in a certain numerical range may be replaced with a value shown in Examples.

In the present disclosure, a combination of two or more preferred aspects is a more preferred aspect.

In the present disclosure, in a case where there are a plurality of kinds of substances corresponding to each component, an amount of each component means a total amount of the plurality of kinds of substances unless otherwise specified.

In the present disclosure, the term “step” includes not only an independent step but also a step that cannot be clearly distinguished from other steps as long as the intended purpose of the step is achieved.

In the present disclosure, “(meth) acrylate” means acrylate or methacrylate.

### (1) First Embodiment

A pellicle according to a first embodiment includes a pellicle frame, a pellicle film, and an adhesive layer. The pellicle film is supported by one end surface (Hereinafter, it is also referred to as a “pellicle film side end surface”.) of the pellicle frame. The adhesive layer is provided on the other end surface (Hereinafter, it is also referred to as an “adhesive layer side end surface”.) of the pellicle frame. At least one of an inner wall surface or an outer wall surface of a surface of the adhesive layer satisfies the following Formula (1).

$$( [ {A}_{2 s} ] / [ {A}_{50 s} ] ) \leq 0.97 \qquad Formula ( 1 )$$

In Formula (1), [A_{2 s}] represents a normalized intensity of a partial structure contained in a main agent component of the adhesive layer, which is obtained by analyzing a first deep portion having a first depth from the surface of the adhesive layer by time-of-flight secondary ion mass spectrometry (time-of-flight secondary ion mass spectrometry (TOF-SIMS)) (Hereinafter, it is also referred to as “TOF-SIMS”.) using a primary ion gun in which an ion source is Bi₃⁺⁺ ions and an irradiation region is 100 μm×100 μm.

Hereinafter, the primary ion gun in which the ion source is Bi₃⁺⁺ ions and an analysis region is 100 μm×100 μm is also simply referred to as a “primary ion gun”.

The first depth is formed by irradiating a 600 μm square area of the surface with a sputter ion gun that is an argon gas cluster ion beam (Ar-GCIB) having a beam voltage of 20 kV and a beam current of 20 nA for a total of 2 seconds.

Hereinafter, a sputter ion gun that is an argon gas cluster ion beam having a beam voltage of 20 kV and a beam current of 20 nA is also simply referred to as a “sputter ion gun (Ar-GCIB)”.

[A_{50 s}] represents a normalized intensity of the partial structure contained in the main agent component of the adhesive layer obtained by analyzing a second deep portion having a second depth by TOF-SIMS.

The second depth is formed by irradiating the area with the sputter ion gun for a total of 50 seconds.

Note that the normalized intensity is a ratio of a peak intensity of the corresponding component to a total intensity value of peaks whose intensity peak positions detected by TOF-SIMS are 45 (m/z) to 2000 (m/z).

TOF-SIMS is a method in which a solid sample is irradiated with a primary ion gun (primary ion), and ions (secondary ions) released from a surface of the solid sample by a collision cascade are mass-separated using a time difference of flight.

In TOF-SIMS, a surface obtained by etching a surface of a solid sample by irradiating the solid sample with a sputtering gun (Ar-GCIB) is analyzed, so that generation and analysis of the secondary ions in a desired portion in a depth direction of the solid sample can be performed. Therefore, when TOF-SIMS is used, a change in a functional group or the like in the depth direction of the solid sample can be quantitatively evaluated.

TOF-SIMS has high mass resolution, and for example, C₃H₃O⁺ and C₄H₇⁺ can be separated and analyzed.

Since the pellicle according to the first embodiment has the above configuration, outgas is less likely to occur. The outgas includes a gas derived from water and a gas derived from a component contained in the adhesive layer. The outgas includes a volatile hydrocarbon (molecular weight: 45 to 100) and a nonvolatile hydrocarbon (molecular weight: 101 to 200).

The fact that Formula (1) is satisfied indicates that the surface of the adhesive layer is modified as described later. It is presumed that the reason why the outgas is less likely to be generated from the pellicle according to the first embodiment is mainly that the partial structure contained in the main agent component of an adhesive as a source of the outgas is reduced in a surface layer of the adhesive layer due to the modification of the surface layer of the adhesive.

The present inventors analyzed the surface of the adhesive layer subjected to a surface treatment in the depth direction by TOF-SIMS. As a result, the present inventors have experimentally confirmed that a normalized intensity of the secondary ions greatly changes from the surface of the adhesive layer to a depth of about 80 nm, and the normalized intensity of the secondary ions does not greatly change at a depth deeper than about 80 nm from the surface of the adhesive layer. The depth of about 80 nm from the surface of the adhesive layer is formed, for example, by irradiating the surface of the adhesive layer with a sputtering gun (Ar-GCIB) for a total of 10 seconds.

When the surface of the adhesive layer is irradiated with the sputtering gun (Ar-GCIB) for a total of 2 seconds, the surface of the adhesive layer is etched, and the depth of the first deep portion becomes about 16 nm from the surface of the adhesive layer. By analyzing the first deep portion with TOF-SIMS, it is possible to detect secondary ions caused by functional groups and the like affected by the surface treatment while suppressing detection of secondary ions (noise) caused by foreign matters attached to the surface of the adhesive layer. In other words, by analyzing the first deep portion by TOF-SIMS, the functional group and the like on the surface of the adhesive layer subjected to the surface treatment can be quantitatively and accurately grasped.

When the surface of the adhesive layer is irradiated with the sputtering gun (Ar-GCIB) for a total of 50 seconds, the surface of the adhesive layer is etched, and the depth of the second deep portion becomes about 400 nm from the surface of the adhesive layer. By analyzing the second deep portion with TOF-SIMS, it is possible to detect secondary ions caused by functional groups and the like that are hardly affected by the surface treatment. In other words, the analysis result of the second deep portion can be regarded as quantitatively representing the functional group and the like on the surface of the adhesive layer before the surface treatment is performed.

([A_{2 s}]/[A_{50 s}]) can be regarded as a change ratio of the partial structure contained in the main agent component by the surface treatment. Therefore, satisfying Formula (1) indicates that the surface of the adhesive layer is modified.

### (1.1) Pellicle

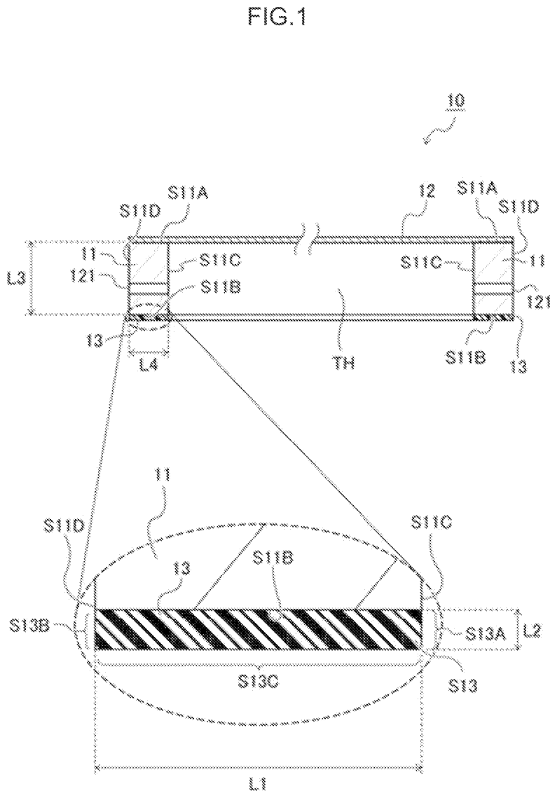

Next, a pellicle 10 according to a first embodiment will be described with reference to FIG. 1.

As illustrated in FIG. 1, the pellicle 10 according to the first embodiment includes a pellicle frame 11, a pellicle film 12, and an adhesive layer 13. The pellicle frame 11 is a cylindrical object. The pellicle frame 11 includes a pellicle film side end surface S11A and an adhesive layer side end surface S11B. The pellicle film 12 is supported by the pellicle film side end surface S11A of the pellicle frame 11. The adhesive layer 13 is provided on the adhesive layer side end surface S11B of the pellicle frame 11.

### (1.1.1) Adhesive Layer

The adhesive layer 13 can be adhered to an original plate. The adhesive layer 13 is provided on the adhesive layer side end surface S11B of the pellicle frame 11, and is a layer that bonds the pellicle frame 11 and the original plate. The original plate will be described later.

The adhesive layer is formed, for example, by applying, heating, drying, curing, surface treatment, or the like to a coating composition as described later.

### (1.1.1.1) Rate of Change in A

In the first embodiment, at least one (Hereinafter, it is also referred to as “inner wall surface S13A or the like”.) of an inner wall surface S13A and an outer wall surface S13B of a surface S13 of the adhesive layer 13 satisfies Formula (1).

$$( [ {A}_{2 s} ] / [ {A}_{50 s} ] ) \leq 0.97 \qquad Formula ( 1 )$$

In Formula (1), [A_{2 s}] represents a normalized intensity of the partial structure contained in the main agent component of the adhesive layer 13 obtained by analyzing the first deep portion having the first depth from the surface S13 of the adhesive layer 13 by TOF-SIMS using the primary ion gun. The first depth can be formed by irradiating a 600 μm square area of the surface S13 of the adhesive layer 13 with the sputter ion gun (Ar-GCIB) for a total of 2 seconds. [A_{50 s}] indicates a normalized intensity of the partial structure contained in the main agent component of the adhesive layer 13 obtained by analyzing the second deep portion having the second depth from the surface S13 of the adhesive layer 13 by TOF-SIMS. The second depth can be formed by irradiating the above-described area with the sputter ion gun (Ar-GCIB) for a total of 50 seconds.

An analysis method of each of [A_{2 s}] and [A_{50 s}] is the same as the analysis method described above.

An upper limit of ([A_{2 s}]/[A_{50 s}]) is 0.97 or less, preferably 0.95 or less, more preferably 0.90 or less, still more preferably 0.80 or less, and particularly preferably 0.70 or less from the viewpoint of suppressing the generation of the outgas. When the upper limit of ([A_{2 s}]/[A_{50 s}]) is 0.97 or less, an amount of outgas caused by hydrocarbon and an amount of outgas caused by water generated can be further suppressed.

A lower limit of ([A_{2 s}]/[A_{50 s}]) can be, for example, 0.05 or more, preferably 0.10 or more, more preferably 0.20 or more, still more preferably 0.30 or more, and particularly preferably 0.50 or more from the viewpoint of suppressing the cost of modifying the surface layer of the adhesive.

From these viewpoints, ([A_{2 s}]/[A_{50 s}]) is preferably 0.05 to 0.97.

In a case where the partial structure contained in the main agent component of the adhesive layer 13 is C₃H₃O⁺ (that is, in a case where a material of the adhesive layer 13 contains an acrylic adhesive (Hereinafter, it is also referred to as an “Ac-based adhesive”)), an upper limit of ([C₃H₃O⁺_{2 s}]/[C₃H₃O⁺_{50 s}]) is 0.97 or less, preferably 0.95 or less, more preferably 0.90 or less, and still more preferably 0.85 or less from the viewpoint of further suppressing the amount of the outgas generated due to hydrocarbon.

A lower limit of ([C₃H₃O⁺_{2 s}]/[C₃H₃O⁺_{50 s}]) can be, for example, 0.05 or more, preferably 0.10 or more, more preferably 0.50 or more, and still more preferably 0.70 or more from the viewpoint of suppressing the cost of modifying the surface layer of the adhesive.

From these viewpoints, ([C₃H₃O⁺_{2 s}]/[C₃H₃O⁺_{50 s}]) is preferably 0.05 to 0.97.

In a case where the partial structure contained in the main agent component of the adhesive layer 13 is CH₃Si⁺ (that is, in a case where a material of the adhesive layer 13 contains a silicone-based adhesive (Hereinafter, it is also referred to as a “Si-based adhesive”)), an upper limit of ([CH₃Si⁺_{2 s}])/([CH₃Si⁺_{50 s}]) is 0.97 or less, preferably 0.95 or less, preferably 0.90 or less, more preferably 0.80 or less, and still more preferably 0.70 or less from the viewpoint of further suppressing the amount of the outgas generated due to hydrocarbons.

A lower limit of ([CH₃Si⁺_{2 s}])/([CH₃Si⁺_{50 s}]) can be, for example, 0.05 or more, preferably 0.10 or more, more preferably 0.30 or more, and still more preferably 0.50 or more from the viewpoint of suppressing the cost of modifying the surface layer of the adhesive.

From these viewpoints, ([CH₃Si⁺_{2 s}])/([CH₃Si⁺_{50 s}]) is preferably 0.05 to 0.97.

In a case where the partial structure contained in the main agent component of the adhesive layer 13 is C₇H₇⁺ (that is, in a case where a material of the adhesive layer 13 contains neither the Ac-based adhesive nor the Si-based adhesive), an upper limit of ([C₇H₇⁺_{2 s}]/[C₇H₇⁺₅₀s]) is 0.97 or less, preferably 0.95 or less, more preferably 0.90 or less, and still more preferably 0.85 or less from the viewpoint of further suppressing the amount of the outgas from hydrocarbons.

A lower limit of ([C₇H₇⁺₂s]/[C₇H₇⁺₅₀s]) can be, for example, 0.05 or more, preferably 0.10 or more, more preferably 0.50 or more, and still more preferably 0.70 or more from the viewpoint of suppressing the cost of modifying the surface layer of the adhesive.

From these viewpoints, ([C₇H₇⁺_{2 s}]/[C₇H₇⁺_{50 s}]) is preferably 0.05 to 0.97.

As illustrated in FIG. 1, the pellicle frame 11 includes an inner peripheral wall S11C and an outer peripheral wall S11D. The “inner wall surface S13A of the adhesive layer 13” refers to a surface of the surface S13 of the adhesive layer 13 on a side of the inner peripheral wall S11C of the pellicle frame 11. The “outer wall surface S13B of the adhesive layer 13” refers to a surface of the surface S13 of the adhesive layer 13 on a side of the outer peripheral wall S11D of the pellicle frame 11.

Since the pellicle 10 has the above configuration, the outgas is less likely to occur.

In the first embodiment, the partial structure contained in the main agent component of the adhesive layer 13 analyzed by TOF-SIMS is preferably C₃H₃O⁺, C₇H₇⁺, or CH₃Si⁺.

The normalized intensity of the partial structure contained in the main agent component of the adhesive layer 13 analyzed by TOF-SIMS depends on the material of the adhesive layer 13, whether or not surface treatment has been performed, and the like. The surface treatment includes a plasma nitriding treatment or an extreme ultra violet (EUV) irradiation treatment (Hereinafter, it is also referred to as “EUV irradiation treatment”). The plasma nitriding treatment and the EUV irradiation treatment will be described later.

The present inventors have experimentally found that determination can be made as follows according to the type of material of the adhesive layer 13 as an index for determining whether or not the inner wall surface S13A or the like has been subjected to the surface treatment.

It has been experimentally found that, in a case where an Ac-based adhesive is used as the material of the adhesive layer 13, a normalized intensity ([C₃H₃O⁺_{50 s}]) of C₃H₃O⁺ in the second deep portion is suitable as an index for determining whether or not the inner wall surface S13A or the like is subjected to the surface treatment. It is presumed that C₃H₃O⁺ is mainly derived from a main chain of the Ac-based adhesive.

It has been experimentally found that in a case where a styrene butadiene-based adhesive (Hereinafter, it is also referred to as “SBR-based adhesive”.) is used as the material of the adhesive layer 13, a normalized intensity ([C₇H₇⁺_{50 s}]) of C₇H₇⁺ in the second deep portion is suitable as an index for determining whether or not the inner wall surface S13A or the like is subjected to the surface treatment. It is presumed that C₇H₇⁺ is mainly derived from a main chain of the SBR-based adhesive.

Moreover, the present inventors have experimentally found that in a case where a silicone-based adhesive (Hereinafter, it is also referred to as a “Si-based adhesive”.) is used as the material of the adhesive layer 13, the sum ([CH₃Si⁺_{50 s}]+[C₃H₉Si⁺_{50 s}]) of a normalized intensity of CH₃Si⁺ in the second deep portion and a normalized intensity of C₃H₉Si⁺ in the second deep portion is suitable as an index for determining whether or not the inner wall surface S13A or the like is subjected to the surface treatment. It is presumed that each of CH₃Si⁺ and C₃H₉Si⁺ is mainly derived from a main chain of the Si-based adhesive.

For example, the partial structure contained in the main agent component of the adhesive layer 13 to be analyzed by TOF-SIMS can be determined as follows.

In the second deep portion, it is determined whether or not the normalized intensity ([C₃H₃O⁺_{50 s}]) of C₃H₃O⁺ detected by TOF-SIMS is greater than or equal to 0.005. In a case where the normalized intensity ([C₃H₃O⁺_{50 s}]) of C₃H₃O⁺ is greater than or equal to 0.005, it is determined that the material of the adhesive layer 13 contains an Ac-based adhesive, and the partial structure contained in the main agent component is C₃H₃O. In this case, the normalized intensity of C₃H₃O⁺ may satisfy Formula (1) (that is, [C₃H₃O⁺_{2 s}]/[C₃H₃O⁺_{50 s} ]≤0.97). As a result, the outgas is less likely to be generated from the pellicle 10.

In the second deep portion, in a case where the normalized intensity ([C₃H₃O⁺_{50 s}]) of C₃H₃O⁺ detected by TOF-SIMS is less than 0.005, it is determined whether or not the sum ([CH₃Si⁺_{50 s}]+[C₃H₉Si⁺_{50 s}]) of the normalized intensity of CH₃Si⁺ and the normalized intensity of C₃H₉Si⁺ is greater than or equal to 0.050. In a case where the sum ([CH₃Si⁺_{50 s}]+[C₃H₉Si⁺_{50 s}]) of the normalized intensity of CH₃Si⁺ and the normalized intensity of C₃H₉Si⁺ is greater than or equal to 0.050, it is determined that the material of the adhesive layer 13 contains a Si-based adhesive, and the partial structure contained in the main agent component is CH₃Si⁺. In this case, the normalized intensity of CH₃Si⁺ may satisfy Formula (1) (that is, [CH₃Si⁺_{2 s}]/[CH₃Si⁺_{50 s} ]≤0.97). As a result, the outgas is less likely to be generated from the pellicle 10.

In the second deep portion, in a case where the normalized intensity ([C₃H₃O⁺_{50 s}]) of C₃H₃O⁺ detected by TOF-SIMS is less than 0.005, and the sum ([CH₃Si⁺_{50 s}]+[C₃H₉Si⁺_{50 s}]) of the normalized intensity of CH₃Si⁺ and the normalized intensity of C₃H₉Si⁺ is less than 0.050, it is determined that the material of the adhesive layer 13 does not contain both the Ac-based adhesive and the Si-based adhesive, and the partial structure contained in the main agent component is C₇H₇⁺. That is, the normalized intensity of C₇H₇⁺ may satisfy Formula (1) (that is, [C₇H₇⁺_{2 s}]/[C₇H₇⁺_{50 s}]<0.97). As a result, the outgas is less likely to be generated from the pellicle 10.

Examples of a method of making the inner wall surface S13A or the like satisfy Formula (1) include a method in which the inner wall surface S13A or the like is subjected to, for example, a plasma nitriding treatment, a plasma nitriding treatment after a dehydration treatment or an EUV irradiation treatment.

In the first embodiment, only one of the inner wall surface S13A and the outer wall surface S13B of the adhesive layer 13 may satisfy Formula (1), or the inner wall surface S13A and the outer wall surface S13B of the adhesive layer 13 may satisfy Formula (1).

When the inner wall surface S13A of the adhesive layer 13 satisfies Formula (1), it is possible to suppress adhesion of dirt to the pellicle film 12 and the original plate when the pellicle 10 is mounted on the original plate in an exposure device. When the outer wall surface S13B of the adhesive layer 13 satisfies Formula (1), it is possible to suppress adhesion of dirt to the pellicle film 12 and the inside of the exposure device when the pellicle 10 is mounted on the original plate in the exposure device.

Among them, from the viewpoint of suppressing adhesion of dirt to the pellicle film 12, the original plate, and the inside of the exposure device, the inner wall surface S13A and the outer wall surface S13B preferably satisfy Formula (1).

### (1.1.1.2) Rate of Change in CNO⁻

(1.1.1.2.1) [CNO⁻_{2 s}]

In the first embodiment, the inner wall surface S13A or the like preferably satisfies the following Formula (2).

$$( [ {{CNO}^{-}}_{2 s} ] / [ {{CNO}^{-}}_{50 s} ] ) \geq 2. \qquad Formula ( 2 )$$

In Formula (2), [CNO⁻_{2 s}] represents a normalized intensity of CNO⁻ obtained by analyzing the first deep portion by TOF-SIMS. [CNO⁻_{50 s}] represents a normalized intensity of CNO⁻ obtained by analyzing the second deep portion by TOF-SIMS.

An analysis method of each of [CNO⁻_{2 s}] and [CNO⁻_{50 s}] is the same as the analysis method described above.

The normalized intensity of CNO⁻ of the adhesive layer 13 analyzed by TOF-SIMS depends on the material of the adhesive layer 13, whether or not plasma nitriding treatment is performed, and the like.

It is presumed that CNO⁻ is mainly derived from an amide bond or a urethane bond contained in the adhesive layer 13 and a nitrogen functional group introduced into the adhesive layer 13 by the plasma nitriding treatment.

The fact that the inner wall surface S13A or the like satisfies Formula (2) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit of ([CNO⁻_{2 s}]/[CNO⁻_{50 s}]) on the inner wall surface S13A or the like can be, for example, 500 or less, preferably 300 or less, more preferably 100 or less, still more preferably 30 or less, and particularly preferably 10 or less, from the viewpoint of suppressing an increase in cost of the plasma nitriding treatment.

A lower limit of ([CNO⁻_{2 s}]/[CNO⁻_{50 s}]) on the inner wall surface S13A or the like can be, for example, 2.00 or more, and preferably 3.00 or more, from the viewpoint of modifying the surface layer of the adhesive layer 13 to a compound derived from the nitrogen functional group to further suppress the generation of the outgas.

([CNO⁻_{2 s}]/[CNO⁻_{50 s}]) on the inner wall surface S13A or the like is preferably 2.00 to 500, more preferably 2.00 to 300, still more preferably 2.00 to 100, particularly preferably 3.00 to 100, still more preferably 3.00 to 30, and still more preferably 3.00 to 10.

An upper limit of ([CNO⁻_{2 s}]/[CNO⁻_{50 s}]) in an adhesive portion of the adhesive layer to the original plate is preferably 500 or less, more preferably 100 or less, still more preferably 10.0 or less, particularly preferably 5.00 or less, still more preferably 3.00 or less, and still more preferably 1.10 or less from the viewpoint of suppressing an increase in cost of the plasma nitriding treatment and easily securing an adhesive force to the original plate.

A lower limit of ([CNO⁻_{2 s}]/[CNO⁻_{50 s}]) in the adhesive portion of the adhesive layer to the original plate is not particularly limited, and is preferably 0.50 or more, and more preferably 0.80 or more.

From these viewpoints, ([CNO⁻_{2 s}]/[CNO⁻_{50 s}]) in the adhesive portion of the adhesive layer to the original plate is preferably 0.50 to 500, more preferably 0.50 to 100, still more preferably 0.50 to 10, particularly preferably 0.50 to 3.00, still more preferably 0.50 to 1.10, and still more preferably 0.80 to 1.10.

From the viewpoint that the surface layer of the adhesive layer 13 is modified to the compound derived from the nitrogen functional group to suppress the generation of outgas, [CNO⁻_{2 s}] is preferably 0.001 or more, more preferably 0.002 or more, still more preferably 0.003 or more, and particularly preferably 0.005 or more. From the viewpoint of suppressing an increase in cost of the plasma nitriding treatment, [CNO⁻_{2 s}] is preferably 0.05 or less, more preferably 0.03 or less, still more preferably 0.02 or less, and particularly preferably 0.01 or less. From these viewpoints, [CNO⁻_{2 s}] is preferably 0.001 to 0.05.

From the viewpoint that the surface layer of the adhesive layer 13 is modified to the compound derived from the nitrogen functional group to suppress the outgas, [CN⁻_{2 s}] is preferably 0.002 or more, more preferably 0.004 or more, still more preferably 0.01 or more, and particularly preferably 0.05 or more. From the viewpoint of suppressing an increase in cost of the plasma nitriding treatment, [CN⁻_{2 s}] is preferably 0.5 or less, more preferably 0.3 or less, still more preferably 0.2 or less, and particularly preferably 0.1 or less. From these viewpoints, [CN⁻_{2 s}] is preferably 0.002 to 0.5.

Examples of a method of making the inner wall surface S13A or the like satisfy Formula (2) include a method in which the inner wall surface S13A or the like is subject to, for example, the plasma nitriding treatment or the plasma nitriding treatment after a dehydration treatment.

In particular, in a case where the adhesive layer 13 does not contain nitrogen atoms, when the plasma nitriding treatment is applied to the inner wall surface S13A or the like, ([CNO⁻_{2 s}]/[CNO⁻_{50 s}]) is dramatically increased. For example, ([CNO⁻_{2 s}]/[CNO⁻_{50 s}]) is 10 or more. This is presumed to be because nitrogen atoms are not easily introduced into the second deep portion while nitrogen atoms are introduced into the first deep portion by the plasma nitriding treatment, and [CNO⁻_{50 s}] that is a denominator of ([CNO⁻_{2 s}]/[CNO⁻_{50 s}]) remains low.

(1.1.1.2.2) [CNO⁻_{6 s}]

In the first embodiment, the inner wall surface S13A or the like preferably satisfies the following Formula (4).

$$( [ {{CNO}^{-}}_{6 s} ] / [ {{CNO}^{-}}_{50 s} ] ) \geq 1.5 \qquad Formula ( 4 )$$

In Formula (4), [CNO⁻_{6 s}] represents a normalized intensity of CNO⁻ obtained by analyzing a third deep portion having a third depth from the surface S13 of the adhesive layer 13 by TOF-SIMS using the primary ion gun. The third depth is formed by irradiating a 600 μm square area of the surface with the sputter ion gun (Ar-GCIB) for a total of 6 seconds. [CNO⁻_{50 s}] represents a normalized intensity of CNO⁻ obtained by analyzing the second deep portion by TOF-SIMS.

The fact that the inner wall surface S13A or the like satisfies Formula (4) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit of ([CNO⁻_{6 s}]/[CNO⁻_{50 s}]) on the inner wall surface S13A or the like can be, for example, 500 or less, preferably 300 or less, more preferably 100 or less, and still more preferably 10 or less from the viewpoint of suppressing an increase in cost of the plasma nitriding treatment.

A lower limit of ([CNO⁻_{6 s}]/[CNO⁻_{50 s}]) is, for example, 2.00 or more, preferably 3.00 or more from the viewpoint of modifying the surface layer of the adhesive layer 13 to the compound derived from the nitrogen functional group to further suppress the generation of the outgas.

From these viewpoints, ([CNO⁻_{6 s}]/[CNO⁻_{50 s}]) is preferably 1.50 to 500, more preferably 2.00 to 100, and still more preferably 3.00 to 10.0.

A method of making the inner wall surface S13A or the like satisfies Formula (4) is similar to the method exemplified as the method of making the inner wall surface S13A or the like satisfies Formula (2), and a method of performing the plasma nitriding treatment after the dehydration treatment on the inner wall surface S13A or the like is preferable.

### (1.1.1.3) Rate of Change in CN⁻

In the first embodiment, the inner wall surface S13A or the like preferably satisfies the following Formula (3).

$$( [ {{CN}^{-}}_{2 s} ] / [ {{CN}^{-}}_{50 s} ] ) \geq 2. \qquad Formula ( 3 )$$

In Formula (3), [CN⁻_{2 s}] represents a normalized intensity of CN⁻ obtained by analyzing the first deep portion by TOF-SIMS. [CN⁻_{50 s}] represents a normalized intensity of CN⁻ obtained by analyzing the second deep portion by TOF-SIMS.

The normalized intensity of CN⁻ of the adhesive layer 13 analyzed by TOF-SIMS depends on the material of the adhesive layer 13, whether or not the plasma nitriding treatment is performed, and the like.

It is presumed that CN⁻ is mainly derived from an amide bond or a urethane bond contained in the adhesive layer 13 and a nitrogen functional group introduced into the adhesive layer 13 by the plasma nitriding treatment.

The fact that the inner wall surface S13A or the like satisfies Formula (3) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit of ([CN⁻_{2 s}]/[CN⁻_{50 s}]) on the inner wall surface S13A or the like can be, for example, 500 or less, preferably 300 or less, more preferably 100 or less, and still more preferably 30 or less from the viewpoint of suppressing an increase in cost of the plasma nitriding treatment.

A lower limit of ([CN⁻_{2 s}]/[CN⁻_{50 s}]) is, for example, 2.00 or more, preferably 3.00 or more from the viewpoint of modifying the surface layer of the adhesive layer 13 to the compound derived from the nitrogen functional group to further suppress the generation of the outgas.

From these viewpoints, ([CN⁻_{2 s}]/[CN⁻_{50 s}]) is preferably 2.00 to 500, more preferably 2.00 to 300, still more preferably 2.00 to 100, particularly preferably 3.00 to 100, and still more preferably 3.00 to 30.

An upper limit of ([CN⁻_{2 s}]/[CN⁻_{50 s}]) in the adhesive portion of the adhesive layer to the original plate is, for example, preferably 500 or less, more preferably 100 or less, still more preferably 10.0 or less, particularly preferably 5.00 or less, still more preferably 3.00 or less, still more preferably 1.10 or less from the viewpoint of suppressing an increase in cost of the plasma nitriding treatment and the viewpoint of easily securing an adhesive force to the original plate.

A lower limit of ([CN⁻_{2 s}]/[CN⁻_{50 s}]) in the adhesive portion of the adhesive layer to the original plate is not particularly limited, and is preferably 0.50 or more, and more preferably 0.80 or more.

From these viewpoints, ([CN⁻_{2 s}]/[CN⁻_{50 s}]) in the adhesive portion of the adhesive layer to the original plate is preferably 0.50 to 500, more preferably 0.50 to 100, still more preferably 0.50 to 10, particularly preferably 0.50 to 3.00, still more preferably 0.50 to 1.10, and still more preferably 0.80 to 1.10.

A method of making the inner wall surface S13A or the like satisfy Formula (3) is similar to the method exemplified as the method of making the inner wall surface S13A or the like satisfy Formula (2).

(1.1.1.3) Change Rate of C₃⁻

In the first embodiment, the inner wall surface S13A or the like preferably satisfies the following Formula (5).

$$( [ {{{C}_{3}}^{-}}_{2 s} ] / [ {{{C}_{3}}^{-}}_{50 s} ] ) \geq 1.1 \qquad Formula ( 5 )$$

In Formula (5), [C₃⁻₂s] represents a normalized intensity of C₃⁻ obtained by analyzing the first deep portion by TOF-SIMS. [C₃⁻₅₀s] represents a normalized intensity of C₃⁻ obtained by analyzing the second deep portion by TOF-SIMS.

An analysis method of each of [C₃⁻₂s] and [C₃⁻_{50 s}] is the same as the analysis method described above.

The normalized intensity of C₃⁻ of the adhesive layer 13 analyzed by TOF-SIMS depends on the material of the adhesive layer 13, whether or not the EUV irradiation treatment has been performed, and the like.

It is presumed that C₃⁻ is mainly derived from carbonization of the inner wall surface S13A or the like due to the surface treatment.

When the inner wall surface S13A or the like satisfies Formula (5), the surface layer of the adhesive layer is carbonized, generation of the outgas is suppressed, and permeation of gas from the inside of the adhesive layer can be suppressed.

An upper limit of ([C₃⁻₂s]/[C₃⁻₅₀s]) can be, for example, 10.0 or less, preferably 5.0 or less, more preferably 3.0 or less, and still more preferably 2.0 or less from the viewpoint of suppressing an increase in cost of the EUV irradiation treatment.

A lower limit of ([C₃⁻₂s]/[C₃⁻₅₀s]) can be, for example, 1.10 or more, preferably 1.20 or more, and more preferably 1.40 or more from the viewpoint of carbonizing and modifying the surface layer of the adhesive layer 13 to suppress the generation of the outgas.

From these viewpoints, ([C₃⁻_{2 s}]/[C₃⁻₅₀s]) is preferably 1.10 to 10.0.

Examples of a method of making the inner wall surface S13A or the like satisfy Formula (5) include a method of performing the EUV irradiation processing on the inner wall surface S13A or the like.

When the EUV irradiation treatment is applied to the inner wall surface S13A or the like, the surface S13 such as the inner wall surface S13A absorbs the EUV and has a high temperature. As a result, the surface S13 such as the inner wall surface S13A subjected to the EUV irradiation treatment is easily carbonized.

In order to further suppress the amount of the outgas generated due to water, an upper limit of ([C₂HO⁻_{2 s}]/[C₂HO⁻_{50 s}]) is preferably 0.97 or less, more preferably 0.95 or less, still more preferably 0.90 or less, and particularly preferably 0.60 or less.

### (1.1.1.4) Nitrogen Atom Concentration

In the first embodiment, a nitrogen atom concentration of the surface S13 such as the inner wall surface S13A is preferably 1.0 at % or more.

The nitrogen atom concentration indicates a ratio (%) of integrated intensity of peak components derived from nitrogen atoms to integrated intensity of peak components of all components in a narrow spectrum of X-ray photoelectron spectroscopy (XPS) (Hereinafter, it is also referred to as “XPS”.) of the inner wall surface S13A or the like. Details of a method of measuring the nitrogen atom concentration will be described later.

The nitrogen atom concentration of the surface S13 such as the inner wall surface S13A being 1.0 at % or more indicates that the surface S13 such as the inner wall surface S13A is not coated with metal.

A lower limit of the nitrogen atom concentration is preferably 1.0 at % or more, preferably 2.0 at % or more, more preferably 3.0 at % or more, and still more preferably 5.0 at % or more.

When the lower limit of the nitrogen atom concentration of the surface S13 such as the inner wall surface S13A is within the above range, the adhesive that is a raw material of the adhesive layer 13 can obtain a sufficient outgassing suppression effect.

In the first embodiment, an upper limit of the nitrogen atom concentration of the surface S13 such as the inner wall surface S13A is preferably 50 at % or less, more preferably 35 at % or less, and still more preferably 20 at % or less.

When the upper limit of the nitrogen atom concentration of the surface S13 such as the inner wall surface S13A is within the above range, the hydrocarbon-based outgas can be reduced.

From these viewpoints, the nitrogen atom concentration is preferably 1.0 at % to 50 at %.

The nitrogen atom concentration of the surface S13 such as the inner wall surface S13A is calculated from an area of peak components analyzed by XPS according to the following XPS analysis method.

An analysis point of the analysis by XPS is different from an analysis point of the analysis by TOF-SIMS.

In other words, the analysis point of the analysis by XPS indicates a site different from a site irradiated with the sputter ion gun (Ar-GCIB) for the depth direction analysis of the adhesive layer 13.

### <XPS Analysis Method>

Device name: AXIS-NOVA (manufactured by Kratos Analytical Limited/manufactured by Shimadzu Corporation)
X-ray used: AlKα ray (1486.6 eV)
Electron energy range: wide scan and narrow scan of −5 eV to 1350 eV (Binding energy)
Raster area: 0.3 mm×0.7 mm

Specifically, the nitrogen atom concentration of the surface S13 such as the inner wall surface S13A is derived by obtaining a ratio (%) of the integrated intensity of the peak components derived from nitrogen atoms to the integrated intensity of the peak components of all components in the XPS narrow spectrum analyzed by the above-described method. All components include a coating (for example, acrylic adhesives, SBR-based adhesives, silicone-based adhesives, and the like). For example, all the components can be determined from the integrated intensity of peak components appearing in the range of 0 eV to 1350 eV. The integrated intensity of the peak components derived from nitrogen atoms can be determined from the integrated intensity appearing in the range of 387 eV to 405 eV.

### (1.1.1.5) Carbon Atom Concentration

In the first embodiment, a carbon atom concentration of the surface S13 such as the inner wall surface S13A is preferably 35 at % or more.

The carbon atom concentration indicates a ratio (%) of integrated intensity of peak components derived from carbon atoms to integrated intensity of peak components of all components in a narrow spectrum of X-ray photoelectron spectroscopy of the inner wall surface S13A or the like. The measurement of the carbon atom concentration is the same as the method of measuring the nitrogen atom concentration except that the integrated intensity of the peak components derived from the carbon atoms is determined from the integrated intensity appearing in a range of 270 eV to 290 eV.

The carbon atom concentration of the surface S13 such as the inner wall surface S13A being 35 at % or more indicates that the surface S13 such as the inner wall surface S13A is not coated with metal.

A lower limit of the carbon atom concentration is preferably 35 at % or more, preferably 50 at % or more, more preferably 60 at % or more, and still more preferably 70 at % or more.

When the lower limit of the carbon atom concentration of the surface S13 such as the inner wall surface S13A is within the above range, the adhesive that is a raw material of the adhesive layer 13 can obtain sufficient adhesiveness and toughness, and high adhesiveness to the original plate and distortion of the original plate can be suppressed. The distortion of the original plate is caused by attachment of the pellicle 10 to the original plate.

An upper limit of the carbon atom concentration is preferably 98 at % or less, more preferably 90 at % or less, and still more preferably 80 at % or less.

When the upper limit of the carbon atom concentration of the surface S13 such as the inner wall surface S13A is within the above range, the hydrocarbon-based outgas can be reduced.

From these viewpoints, the carbon atom concentration is preferably 35 at % to 98 at %.

Note that the theoretical value (value excluding hydrogen) of the carbon atom concentration of the silicone resin [(SiO(CH₃)₂)ₙ] is 50 at % or more. A measured value of the carbon atom concentration of an Ac-based adhesive 1 used in Examples was 76.0 at %. A measured value of the carbon atom concentration of an Ac-based adhesive 2 used in Examples was 71.5 at %. A measured value of the carbon atom concentration of an SBR-based adhesive used in Examples was 81.8 at %. A method of measuring the carbon atom concentration of the Ac-based adhesive 1, the Ac-based adhesive 2, and the SBR-based adhesive is the same as the method of measuring the carbon atom concentration described later.

### (1.1.1.6) Glass Transition Temperature

A glass transition temperature Tg of the adhesive layer 13 is preferably higher than −25° C. and lower than 10° C. As a result, the adhesive layer 13 has an adhesive force in an operating temperature range of the pellicle (for example, 20° C. or higher), and is more hardly peeled off from the original plate even when exposed to a high temperature environment.

A lower limit of the glass transition temperature Tg of the adhesive layer 13 is preferably higher than −25° C., more preferably −22° C. or higher, still more preferably −20° C. or higher, and most preferably −18° C. or higher from the viewpoint of making the adhesive layer more difficult to be peeled off from the original plate even when exposed to a high temperature environment.

From the viewpoint of imparting adhesiveness at normal temperature, an upper limit of the glass transition temperature Tg of the adhesive layer 13 is preferably less than 10° C., more preferably 5° C. or less, and still more preferably 0° C. or less.

A method of measuring the glass transition temperature (Tg) of the adhesive layer 13 is in accordance with JIS K7112.

Specifically, the glass transition temperature (Tg) of the adhesive layer 13 is measured using a differential scanning calorimetry (DSC) at a temperature rising rate of 20° C./min under nitrogen.

### (1.1.1.7) Size of Adhesive Layer

A width L1 (see FIG. 1) of the adhesive layer 13 is preferably 1.0 mm to 4.0 mm, and more preferably 1.2 mm to 3.8 mm. A thickness L2 (see FIG. 1) of the adhesive layer 13 is preferably 0.1 mm to 2 mm, and more preferably 0.2 mm to 1 mm.

### (1.1.2) Pellicle Frame

The pellicle frame 11 supports the pellicle film 12.

The pellicle frame 11 is a cylindrical object. In the first embodiment, the pellicle frame 11 includes a through hole TH and a vent hole 121. The through hole TH is a space through which exposure light having passed through the pellicle film 12 passes to reach the original plate at the time of exposure. The through hole TH allows an internal space of the pellicle 10 and an external space of the pellicle 10 to communicate with each other when the pellicle frame 11 is attached to the original plate. The “internal space of the pellicle 10” indicates a space surrounded by the pellicle 10 and the original plate (not illustrated). The “external space of the pellicle 10” indicates a space not surrounded by the pellicle 10 and the original plate (not illustrated).

The material, shape, and the like of the pellicle frame 11 are not particularly limited as long as it is a frame capable of supporting the pellicle film 12. As a material of the pellicle frame 11, aluminum, titanium, stainless steel, a ceramic-based material (for example, silicon, glass, and the like), a resin such as polyethylene, or the like may be contained.

A dustproof adhesive layer may be formed on the inner peripheral wall S11C of the pellicle frame 11. As a result, for example, it is possible to suppress dust or the like that has entered the internal space through the vent hole 121 from reaching the original plate.

A surface of the dustproof adhesive layer is subjected to the surface treatment in the same manner as the adhesive layer 13. The material of the dustproof adhesive layer may be the same as or different from the material of the adhesive layer 13.

The shape of the pellicle frame is, for example, a rectangular shape from a thickness direction of the pellicle frame. The rectangular shape may be a square or a rectangle. The rectangular pellicle frame may be configured of four sides when viewed from the thickness direction.

When the shape of the pellicle frame is the rectangle shape, a length of one side in a longitudinal direction is preferably 200 mm or less. The size and the like of the pellicle frame are standardized by the type of exposure device. That the length of one side of the pellicle frame in the longitudinal direction is 200 mm or less satisfies a size standardized for exposure using EUV light.

A length of one side in a lateral direction can be, for example, 5 mm to 180 mm, and is preferably 80 mm to 170 mm, and more preferably 100 mm to 160 mm.

A height (that is, a length of the pellicle frame in the thickness direction) of the pellicle frame is not particularly limited, and is preferably 3.0 mm or less, more preferably 2.4 mm or less, and still more preferably 2.375 mm or less. Thereby, the pellicle frame satisfies a size standardized for EUV exposure. The height of the pellicle frame standardized for EUV exposure is, for example, 2.375 mm.

The mass of the pellicle frame is not particularly limited, and is preferably 20 g or less, and more preferably 15 g or less. Thereby, the pellicle frame is suitable for EUV exposure applications.

### (1.1.3) Pellicle Film

The pellicle film 12 prevents foreign matter from adhering to the surface of the original plate and transmits exposure light during exposure. The foreign matter includes dust. Examples of the exposure light include deep ultraviolet (DUV) light, EUV, and the like. The EUV indicates light having a wavelength of 1 nm to 100 nm. The wavelength of the EUV light is preferably 5 nm to 13.5 nm.

The pellicle film 12 covers an entire opening of the through hole TH of the pellicle frame 11 on a side of the pellicle film side end surface S11A. The pellicle film 12 may be directly supported on the pellicle film side end surface S11A of the pellicle frame 11, or may be supported via an adhesive layer (Hereinafter, it is also referred to as a “film adhesive layer”).

In a case where the pellicle film 12 is supported by the pellicle frame 11 via the film adhesive layer, a surface of a side surface of the film adhesive layer is preferably subjected to the surface treatment in the same manner as the adhesive layer 13. The material of the film adhesive layer may be the same as or different from the material of the adhesive layer 13, and may be a cured product of a known adhesive.

A film thickness of the pellicle film 12 is preferably 1 nm to 200 nm.

The material of the pellicle film 12 is not particularly limited, and examples thereof include a carbon-based material, SiN, and polysilicon. The carbon-based material includes carbon nanotubes (Hereinafter, it is also referred to as “CNT”). Among them, the material of the pellicle film 12 preferably contains the CNT. The CNT may be a single-wall CNT, a multi-wall CNT, or a single-wall CNT and a multi-wall CNT.

The pellicle film 12 may be a nonwoven fabric structure. The nonwoven fabric structure is formed by, for example, a fiber shaped CNT.

### (1.2) Exposure Original Plate

An exposure original plate according to the first embodiment includes the original plate and the pellicle 10 according to the first embodiment. The original plate has a pattern. The pellicle 10 is attached to a surface of the original plate on a side having the pattern.

Since the exposure original plate according to the first embodiment includes the pellicle 10, the same effect as that of the pellicle 10 is obtained.

The original plate may be formed by, for example, laminating a support substrate, a reflection layer, and an absorber layer in this order. In this case, the pellicle 10 is mounted on a side of the original plate on which the reflection layer and the absorber layer are provided.

When the absorber layer partially absorbs light (for example, EUV), a desired image is formed on a sensitive substrate (for example, a semiconductor substrate with a photoresist film). Examples of the reflection layer include a multilayer film of molybdenum (Mo) and silicon (Si). The material of the absorber layer may be a material having high absorbability such as EUV. Examples of a material having high absorbability such as EUV include chromium (Cr) and tantalum nitride.

### (1.3) Exposure Device

An exposure device according to the first embodiment includes a light source, the exposure original plate according to the first embodiment, and an optical system. The light source emits exposure light. The optical system guides the exposure light emitted from the light source to the exposure original plate. The exposure original plate is disposed such that the exposure light emitted from the light source passes through the pellicle film and is applied to the original plate.

Therefore, the exposure device according to the first embodiment obtains the same effect as that of the exposure original plate according to the first embodiment. Moreover, since the exposure device according to the first embodiment has the above-described configuration, in addition to being able to form a pattern (for example, a line width of 32 nm or less) miniaturized by EUV or the like, pattern exposure in which resolution failure due to foreign matter is reduced can be performed even in a case of using EUV in which resolution failure due to foreign matter tends to be a problem.

The exposure light is preferably EUV. Since EUV has a short wavelength, EUV is easily absorbed by a gas such as oxygen or nitrogen. Therefore, exposure with EUV light is performed in a vacuum environment.

As the light source, a known light source can be used. As the optical system, a known optical system can be used.

### (1.4) Method of Manufacturing Pellicle Film

A method of manufacturing the pellicle according to the first embodiment (Hereinafter, it is also referred to as a “manufacturing method of a pellicle”.) is a method of manufacturing the pellicle 10, and includes an adhesive layer forming step described later. Thereby, the pellicle 10 in which the inner wall surface S13A or the like satisfies Formula (1) is obtained.

### (1.4.1) Adhesive Layer Forming Step

In the adhesive layer forming step, the adhesive layer 13 is formed by applying a coating composition to the adhesive layer side end surface S11B of the pellicle frame 11, and subjecting at least one of an inner wall surface or an outer wall surface (Hereinafter, also referred to as an “inner wall surface or the like of an adhesive layer precursor”.) of a surface of an adhesive layer precursor on which the adhesive layer precursor is formed by heating to a plasma nitriding treatment or an extreme ultraviolet irradiation treatment.

When the plasma nitriding treatment or the extreme ultraviolet irradiation treatment is performed, the adhesive layer precursor may be subjected to the treatment, the treatment may be performed in a state where an adhesive protecting film is attached to an adhesive portion (corresponding to sign S13C in FIG. 1) of the adhesive layer to the original plate, or the treatment may be performed in a state where the pellicle is attached to the original plate. From the viewpoint of easily securing an adhesive force of the adhesive layer to the original plate, it is preferable to perform the treatment in a state where the adhesive protecting film is attached to the adhesive portion of the adhesive layer to the original plate.

The inner wall surface of the adhesive layer precursor is a surface corresponding to the inner wall surface S13A of the adhesive layer 13. The outer wall surface of the adhesive layer precursor is a surface corresponding to the outer wall surface S13B of the adhesive layer 13.

### (1.4.2) Coating Composition

The coating composition contains a compound selected from various polymers, solvents, crosslinking agents, catalysts, initiators, and the like depending on the adhesive layer to be formed. The coating composition is a precursor of the adhesive layer precursor (adhesive composition). That is, when the coating composition is cured, the adhesive composition is obtained.

### (1.4.3) Adhesive Composition

Examples of the adhesive composition include an Ac-based adhesive, a Si-based adhesive, an SBR-based adhesive, a urethane-based adhesive, an olefin-based adhesive, a polyamide-based adhesive, and a polyester-based adhesive. Among them, the material of the adhesive layer 13 is preferably an Ac-based adhesive, a Si-based adhesive, or an SBR-based adhesive from the viewpoint of reducing the amount of the outgas generated from the pellicle 10.

### (1.4.3.1) Ac-based Adhesive

The Ac-based adhesive preferably contains a (meth) acrylic acid alkyl ester copolymer.

### (1.4.3.1.1) (Meth) Acrylic Acid Alkyl Ester Copolymer

The (meth) acrylic acid alkyl ester copolymer preferably contains a copolymer of a (meth) acrylic acid alkyl ester monomer and a monomer (Hereinafter, also referred to as a “functional group-containing monomer”.) having a functional group reactive with at least one of an isocyanate group, an epoxy group, and an acid anhydride.

Hereinafter, the copolymer of the (meth) acrylic acid alkyl ester monomer and the functional group-containing monomer is also referred to as “the copolymer”.

When the Ac-based adhesive contains the (meth) acrylic acid alkyl ester copolymer, the pellicle is hardly peeled off from the original plate even when exposed to a high temperature environment (for example, a temperature environment of more than 60° C. or 60° C.), and the occurrence of adhesive residue can be suppressed.

The term “adhesive residue” means that at least a part of the adhesive for pellicle remains on the original plate after the pellicle is peeled off from the original plate.

A weight average molecular weight (Mw) of the (meth) acrylic acid alkyl ester copolymer is preferably 30,000 to 2,500,000, more preferably 50,000 to 1,500,000, and still more preferably 70,000 to 1,200,000.

When an upper limit of the weight average molecular weight (Mw) of the (meth) acrylic acid alkyl ester copolymer is 2,500,000 or less, the solution viscosity can be controlled within an easily processable range even when the solid content concentration of the coating composition is increased. The upper limit of the weight average molecular weight (Mw) of the (meth) acrylic acid alkyl ester copolymer is preferably 2,500,000 or less, more preferably 1,500,000 or less, and still more preferably 1,200,000 or less.

When a lower limit of the weight average molecular weight (Mw) of the (meth) acrylic acid alkyl ester copolymer is 30,000 or more, the pellicle is more hardly peeled off from the original plate even when exposed to a high temperature environment (for example, 60° C.), and the occurrence of adhesive residue can be suppressed. The lower limit of the weight average molecular weight (Mw) of the (meth) acrylic acid alkyl ester copolymer is preferably 30,000 or more, more preferably 50,000 or more, and still more preferably 70,000 or more.

A method of measuring the weight average molecular weight of the (meth) acrylic acid alkyl ester copolymer is gel permeation chromatography (GPC), and the details of the measurement method will be described later in Examples.

For example, in general, the weight average molecular weight (Mw) tends to increase as the monomer concentration during the polymerization reaction increases, and the weight average molecular weight (Mw) tends to increase as an amount of the polymerization initiator decreases or as the polymerization temperature decreases. The weight average molecular weight (Mw) can be controlled by adjusting the monomer concentration, the amount of the polymerization initiator, and the polymerization temperature.

A number average molecular weight (Mn) of the (meth) acrylic acid alkyl ester copolymer is preferably 5,000 to 500,000, more preferably 8,000 to 300,000, still more preferably 10,000 to 200,000, and most preferably 20,000 to 200,000.

When an upper limit of the number average molecular weight (Mn) of the (meth) acrylic acid alkyl ester copolymer is 500,000 or less, the solution viscosity can be controlled within an easily processable range even when the solid content concentration of the coating composition is increased. The upper limit of the number average molecular weight (Mn) of the (meth) acrylic acid alkyl ester copolymer is preferably 500,000 or less, more preferably 300,000 or less, and still more preferably 200,000 or less.

When a lower limit of the number average molecular weight (Mn) of the (meth) acrylic acid alkyl ester copolymer is 5,000 or more, the pellicle is more hardly peeled off from the original plate even when exposed to a high temperature environment (for example, 60° C.), and the occurrence of adhesive residue can be suppressed. The lower limit of the number average molecular weight (Mn) of the (meth) acrylic acid alkyl ester copolymer is preferably 5,000 or more, more preferably 8,000 or more, still more preferably 10,000 or more, and most preferably 20,000 or more.

A measurement method of the number average molecular weight (Mn) of the (meth) acrylic acid alkyl ester copolymer is the same as a measurement method described in Examples.

A ratio (hereinafter, also referred to as “Mw/Mn”) of the weight average molecular weight (Mw)/the number average molecular weight (Mn) of the (meth) acrylic acid alkyl ester copolymer is preferably 1.0 to 10.0, more preferably 2.5 to 9.0, still more preferably 2.5 to 8.0, and most preferably 3.0 to 7.0.

When Mw/Mn is within the above range, the production of the (meth) acrylic acid alkyl ester copolymer is easy, and the occurrence of adhesive residue can be suppressed.

When an upper limit of Mw/Mn is 10.0 or less, the occurrence of adhesive residue can be suppressed. The upper limit of Mw/Mn is preferably 10.0 or less, more preferably 9.0 or less, still more preferably 8.0 or less, and most preferably 7.0 or less.

When a lower limit of Mw/Mn is 1.0 or more, a (meth) acrylic acid alkyl ester copolymer can be easily produced. The lower limit of Mw/Mn is preferably 1.0 or more, more preferably 2.0 or more, still more preferably 2.5 or more, and most preferably 3.0 or more.

The (meth) acrylic acid alkyl ester monomer preferably contains a (meth) acrylic acid alkyl ester monomer having an alkyl group having 1 to 14 carbon atoms. Examples of the (meth) acrylic acid alkyl ester monomer having an alkyl group having 1 to 14 carbon atoms include a (meth) acrylic acid ester monomer of a linear chain aliphatic alcohol and a (meth) acrylic acid ester monomer of a branched chain aliphatic alcohol.

Examples of the (meth) acrylic acid ester monomer of the linear chain aliphatic alcohol include methyl (meth) acrylate, ethyl (meth) acrylate, butyl (meth) acrylate, propyl (meth) acrylate, hexyl (meth) acrylate, octyl (meth) acrylate, decyl (meth) acrylate, dodecyl (meth) acrylate, and lauryl (meth) acrylate.

Examples of the (meth) acrylic acid ester monomer of the branched chain aliphatic alcohol include isobutyl (meth) acrylate, isoamyl (meth) acrylate, 2-ethylhexyl (meth) acrylate, isooctyl (meth) acrylate, and isononyl (meth) acrylate. These may be used alone or in combination of two or more kinds thereof.

Among them, the (meth) acrylic acid alkyl ester monomer preferably has at least one of an alkyl group having 1 to 3 carbon atoms and an alicyclic alkyl group.

Hereinafter, the (meth) acrylic acid alkyl ester monomer having at least one of an alkyl group having 1 to 3 carbon atoms and an alicyclic alkyl group is also referred to as a “high-Tg monomer”. “Tg” refers to a glass transition temperature.

In order to further reduce the amount of outgas generated, the (meth) acrylic acid alkyl ester monomer is more preferably an acrylic acid alkyl ester monomer having an alkyl group having 1 to 3 carbon atoms or an alicyclic alkyl group, still more preferably an acrylic acid alkyl ester monomer having an alkyl group having 1 to 3 carbon atoms, and still more preferably an acrylic acid alkyl ester monomer having an alkyl group having 1 to 2 carbon atoms. In a case where the (meth) acrylic acid alkyl ester monomer is an acrylic acid alkyl ester monomer having an alicyclic alkyl group, the number of carbon atoms of the alicyclic alkyl group is preferably 5 to 10 from the viewpoint of availability.

When the (meth) acrylic acid alkyl ester monomer contains a high-Tg monomer, the pellicle is more hardly peeled off from the original plate even when exposed to a high-temperature atmosphere.

Specific examples of the high-Tg monomer include methyl acrylate, ethyl acrylate, propyl acrylate, isopropyl acrylate, cyclohexyl acrylate, dicyclopentanyl acrylate, methyl methacrylate, ethyl methacrylate, propyl methacrylate, isopropyl methacrylate, cyclohexyl methacrylate, and dicyclopentanyl methacrylate.

The content of the (meth) acrylic acid alkyl ester monomer is preferably 80 parts by mass to 99.5 parts by mass, more preferably 85 parts by mass to 99.5 parts by mass, and still more preferably 87 parts by mass to 99.5 parts by mass, based on 100 parts by mass of the total amount of monomers constituting the copolymer.

When the content of the (meth) acrylic acid alkyl ester monomer is in a range of 80 parts by mass to 99.5 parts by mass, an appropriate adhesive force can be realized.

The functional group-containing monomer is a monomer copolymerizable with a (meth) acrylic acid alkyl ester monomer. The functional group-containing monomer has a functional group having reactivity with at least one of an isocyanate group, an epoxy group, and an acid anhydride.

Examples of the functional group-containing monomer include a carboxy group-containing monomer, a hydroxy group-containing monomer, and an epoxy group-containing monomer.

Examples of the carboxy group-containing monomer include (meth) acrylic acid, itaconic acid, (meth) acrylic acid itaconic acid, maleic acid, and crotonic acid.

Examples of the hydroxy group-containing monomer include 2-hydroxyethyl (meth) acrylate, 3-hydroxypropyl (meth) acrylate, 2-hydroxypropyl (meth) acrylate, and 4-hydroxybutyl (meth) acrylate.

Examples of the epoxy group-containing monomer include glycidyl (meth) acrylate.

These may be used alone or in combination of two or more kinds thereof.

In particular, from the viewpoint of copolymerizability, versatility, and the like, the functional group-containing monomer preferably contains hydroxy group-containing (meth) acrylic acid having a hydroxyalkyl group having 2 to 4 carbon atoms or glycidyl (meth) acrylate that is an epoxy group-containing monomer. Examples of the hydroxy group-containing (meth) acrylic acid having a hydroxyalkyl group having 2 to 4 carbon atoms include 2-hydroxyethyl (meth) acrylate, 2-hydroxypropyl (meth) acrylate, 2-hydroxybutyl (meth) acrylate, and 4-hydroxybutyl (meth) acrylate.

The content of the functional group-containing monomer is preferably, for example, 0.5 parts by mass to 20 parts by mass with respect to 100 parts by mass of the total amount of monomers constituting the copolymer.

From the viewpoint of improving an adhesive force of the adhesive layer, a lower limit of the content of the functional group-containing monomer is more preferably 1 part by mass or more, still more preferably 2 parts by mass or more, and particularly preferably 3 parts by mass or more, with respect to 100 parts by mass of the total amount of monomers constituting the (meth) acrylic acid alkyl ester copolymer.

An upper limit of the content of the functional group-containing monomer is more preferably 15 parts by mass or less, still more preferably 10 parts by mass or less with respect to 100 parts by mass of the total amount of monomers constituting the (meth) acrylic acid alkyl ester copolymer from the viewpoint of setting the adhesive force of the adhesive layer to an appropriate adhesive force.

### (1.4.3.1.2) Polymerization Method

A polymerization method of the (meth) acrylic acid alkyl ester copolymer is not particularly limited, and examples thereof include solution polymerization, bulk polymerization, emulsion polymerization, and various radical polymerizations.

The (meth) acrylic acid alkyl ester copolymer obtained by these polymerization methods may be any of a random copolymer, a block copolymer, a graft copolymer, and the like.

### (1.4.3.1.3) Polymerization Solvent

A reaction solution contains a polymerization solvent.

In the solution polymerization, as a polymerization solvent, for example, propyl acetate, ethyl acetate, toluene, or the like can be used. Thereby, the viscosity of the copolymer solution can be adjusted. As a result, a thickness and a width of the coating composition are easily controlled during polymerization.

Examples of a diluting solvent include propyl acetate, acetone, ethyl acetate, and toluene.

The viscosity of the copolymer solution is preferably 1,000 Pa·s or less, more preferably 500 Pa·s or less, and still more preferably 200 Pa·s or less.

The viscosity of the copolymer solution is a viscosity when a temperature of the copolymer solution is 25° C., and can be measured with an E-type viscometer.

### (1.4.3.1.4) Solution Polymerization

An example of the solution polymerization is a method in which a polymerization initiator is added to a mixed solution of monomers under a stream of an inert gas such as nitrogen, and a polymerization reaction is performed at 50° C. to 100° C. for 4 hours to 30 hours.

Examples of the polymerization initiator include an azo-based polymerization initiator and a peroxide-based polymerization initiator. Examples of the azo-based polymerization initiator include 2,2′-azobisisobutyronitrile (AIBN), 2,2′-azobis-2-methylbutyronitrile, 2,2′-azobis (2-methylpropionic acid) dimethyl, and 4,4′-azobis-4-cyanovaleric acid. Examples of the peroxide-based polymerization initiator include benzoyl peroxide.

The content of the polymerization initiator is preferably 0.01 parts by mass to 2.0 parts by mass with respect to 100 parts by mass of the total amount of all monomers constituting the (meth) acrylic acid alkyl ester copolymer.

In the solution polymerization, in addition to the polymerization initiator, a chain transfer agent, an emulsifier, and the like may be added to a mixed solution of monomers. As the chain transfer agent, emulsifier, and the like, known agents can be suitably selected and used.

An amount of the polymerization initiator remaining in the adhesive layer is preferably small. As a result, the amount of outgas generated during exposure can be reduced.

Examples of a method of reducing an amount of the polymerization initiator remaining in the adhesive layer include a method in which an amount of the polymerization initiator added when polymerizing the (meth) acrylic acid alkyl ester copolymer is minimized, a method in which a polymerization initiator that is easily thermally decomposed is used, and a method in which the adhesive is heated to a high temperature for a long time in a step of applying and drying the adhesive to decompose the polymerization initiator in the drying step.

A 10 hour half-life temperature is used as an index representing a thermal decomposition rate of the polymerization initiator. The “half-life” indicates a time until half of the polymerization initiator is decomposed. The “10 hour half-life temperature” refers to a temperature at which the half-life is 10 hours.

As the polymerization initiator, it is preferable to use a polymerization initiator having a low 10 hour half-life temperature. As the 10 hour half-life temperature is lower, the polymerization initiator is more likely to be thermally decomposed. As a result, it hardly remains in the adhesive layer.

The 10 hour half-life temperature of the polymerization initiator is preferably 80° C. or lower, and more preferably 75° C. or lower.

Examples of the azo-based polymerization initiator having a low 10 hour half-life temperature include 2,2′-azobis (4-methoxy-2,4-dimethylvaleronitrile) (10 hour half-life temperature: 30° C.), 2,2′-azobisisobutyronitrile (10 hour half-life temperature: 65° C.), 2,2-azobis (2,4-dimethylvaleronitrile) (10 hour half-life temperature: 51° C.), dimethyl 2,2′-azobis (2-methylpropionate) (10 hour half-life temperature: 66° C.), and 2,2′-azobis (2-methylbutyronitrile) (10 hour half-life temperature: 67° C.).

Examples of the peroxide-based polymerization initiator having a low 10 hour half-life temperature include dibenzoyl peroxide (10 hour half-life temperature: 74° C.) and dilauroyl peroxide (10 hour half-life temperature: 62° C.).

### (1.4.3.1.5) Crosslinking Agent

The Ac-based adhesive preferably contains a reaction product of a (meth) acrylic acid alkyl ester copolymer and a crosslinking agent. As a result, a cohesive force of the resulting adhesive layer can be improved, adhesive residues when the pellicle is peeled off from a photomask can be suppressed, and the adhesive force at a high temperature (for example, a temperature environment of more than 60° C. or 60° C.) can be improved.

The crosslinking agent has at least one of an isocyanate group, an epoxy group, and an acid anhydride.

Examples of the crosslinking agent include a monofunctional epoxy compound, a polyfunctional epoxy compound, an acid anhydride-based compound, a metal salt, a metal alkoxide, an aldehyde-based compound, a non-amino resin-based amino compound, a urea-based compound, an isocyanate-based compound, a metal chelate-based compound, a melamine-based compound, and an aziridine-based compound.

Among them, the crosslinking agent is more preferably at least one of a monofunctional epoxy compound, a polyfunctional epoxy compound, an isocyanate-based compound, and an acid anhydride-based compound, and more preferably an acid anhydride-based compound, from the viewpoint of excellent reactivity with the functional group component of the (meth) acrylic acid alkyl ester copolymer.

Examples of the monofunctional epoxy compound include glycidyl (meth) acrylate, glycidyl acetate, butyl glycidyl ether, and phenyl glycidyl ether.

Examples of the polyfunctional epoxy compound include neopentyl glycol diglycidyl ether, polyethylene glycol diglycidyl ether, bisphenol A diglycidyl ether, bisphenol F diglycidyl ether, phthalic acid diglycidyl ester, dimer acid diglycidyl ester, triglycidyl isocyanurate, diglycerol triglycidyl ether, sorbitol tetraglycidyl ether, N,N,N′,N′-tetraglycidyl m-xylenediamine, 1,3-bis (N,N-diglycidylaminomethyl) cyclohexane, N,N,N′,N′-tetraglycidyl diaminodiphenylmethane, and the like.

Examples of the acid anhydride-based compound include aliphatic dicarboxylic anhydrides and aromatic polycarboxylic anhydrides.

Examples of the aliphatic dicarboxylic anhydride include maleic anhydride, hexahydrophthalic anhydride, hexahydro-4-methylphthalic anhydride, bicyclo[2.2.1] heptane-2,3-dicarboxylic anhydride, 2-methylbicyclo [2.2.1] heptane-2,3-dicarboxylic anhydride, and tetrahydrophthalic anhydride.

Examples of the aromatic polycarboxylic anhydride include phthalic anhydride and trimellitic anhydride.

Examples of the isocyanate-based compound include xylylene diisocyanate, hexamethylene diisocyanate, tolylene diisocyanate, multimers, derivatives, and polymers thereof. These may be used alone or in combination of two or more kinds thereof.

The crosslinking agent may be a product. Examples of the product of the crosslinking agent include “RIKACID MH-700G” manufactured by New Japan Chemical Co., Ltd.

It is preferable that the adhesive layer contains a reaction product of the copolymer and a crosslinking agent, and the content of the crosslinking agent is 0.01 parts by mass to 3.00 parts by mass with respect to 100 parts by mass of the total amount of monomers constituting the copolymer.

The content of the crosslinking agent is preferably 0.01 parts by mass to 3.00 parts by mass with respect to 100 parts by mass of the total amount of monomers constituting the copolymer, more preferably 0.10 parts by mass to 3.00 parts by mass, and still more preferably 0.1 parts by mass to 2.00 parts by mass from the viewpoint of obtaining an adhesive for pellicle in which adhesive residues are less likely to occur.

When an upper limit of the content of the crosslinking agent is 3.00 parts by mass or less, the crosslinking density of the (meth) acrylic acid alkyl ester copolymer does not become too high. Therefore, it is considered that the adhesive absorbs the stress applied to the original plate, and the influence of the adhesive layer on the flatness of the original plate is alleviated. The upper limit of the content of the crosslinking agent is preferably 2.00 parts by mass or less, and more preferably 1.00 parts by mass or less.

On the other hand, it is considered that when a lower limit of the content of the crosslinking agent is 0.01 parts by mass or more, the crosslinking density is not excessively reduced, so that handleability during the manufacturing process is maintained, and adhesive residues hardly occur when the pellicle is peeled from the original plate.

When the content of the crosslinking agent is in a range of 0.01 parts by mass to 3.00 parts by mass, a pellicle in which the occurrence of adhesive residues is further suppressed is obtained.

### (1.4.3.1.6) Catalyst

The coating composition may further contain a catalyst. This makes it possible to further accelerate the curing of the (meth) acrylic acid alkyl ester copolymer.

Examples of the catalyst include an amine-based catalyst. Examples of the amine-based catalyst include octylate of (1,8-diazabicyclo-(5.4.0) undecene-7) and triethylenediamine. The amine-based catalyst may be a product of San-Apro Ltd., such as “DBU”, “DBN”, “U-CAT”, “U-CAT SA1”, or “U-CAT SA102”.

The content of the catalyst is preferably 0.01 parts by mass to 3.00 parts by mass, and more preferably 0.10 parts by mass to 1.00 parts by mass, based on 100 parts by mass of the (meth) acrylic acid alkyl ester copolymer.

### (1.4.3.1.7) Surface Modifier

It is preferable that the coating composition does not contain a surface modifier. As a result, the amount of outgas generated can be suppressed.

### (1.4.3.1.8) Additives

The coating composition may contain additives such as a filler, a pigment, a diluent, an anti-aging agent, and a tackifier as necessary. These additives may be used singly or in combination of two or more kinds thereof.

### (1.4.3.1.9) Diluent Solvent

The coating composition may contain a diluent solvent. Thereby, the viscosity of the coating composition can be adjusted. As a result, when the coating composition is applied to the other end surface of the pellicle frame, a thickness and a width of the coating composition are easily controlled.

Examples of a diluting solvent include propyl acetate, acetone, ethyl acetate, and toluene.

The viscosity of the coating composition is preferably 50 Pa·s or less, more preferably 10 Pa·s to 40 Pa·s, and still more preferably 20 Pa·s to 30 Pa·s.

The viscosity of the coating composition is a viscosity when a temperature of the coating composition is 25° C., and can be measured by an E-type viscometer.

### (1.4.3.2) SBR-based Adhesive

As the SBR-based adhesive, a hydrogenated styrene-isoprene block copolymer or a hot melt adhesive obtained by adding a mineral oil as a softener to an alicyclic saturated hydrocarbon resin can be used.

The SBR-based adhesive contains a styrene-based thermoplastic elastomer (A) and a tackifier resin (B).

The styrene-based thermoplastic elastomer (A) is a polymer containing a constituent unit derived from styrene, and is preferably a block copolymer of styrene and an olefin other than styrene. As the olefin other than styrene, monomers capable of forming a side chain having a bulky branched structure in the polymer block, such as isoprene and 4-methyl-1-pentene, are preferable. Among them, isoprene is particularly preferable as an olefin other than styrene.

The total proportion of the constituent units derived from styrene contained in the styrene-based thermoplastic elastomer (A) is preferably 35 mass % or less, and more preferably 20 mass % or less, with respect to the total amount of the styrene-based thermoplastic elastomer (A). When the content ratio of the constituent unit derived from styrene is within the above range, deterioration of compatibility with various additives can be suppressed, and separation of the styrene-based thermoplastic elastomer and the additive can be suppressed.

The styrene-based thermoplastic elastomer (A) preferably contains a triblock copolymer (Hereinafter, it is also referred to as “SIS”.) or a hydrogenated product of the triblock copolymer (Hereinafter, it is also referred to as “H-SIS”). The SIS has a first polystyrene block, a polyisoprene block containing an isopropenyl group (1-methylethenyl group (—C(═CH₂)CH₃) in a side chain, and a second polystyrene block. A triblock copolymer containing a polymer block having a bulky branched structure in a side chain, such as an isopropenyl group, absorbs distortion of the pellicle frame and easily suppresses distortion of the original plate. Note that the “hydrogenated product of the triblock copolymer” means one in which preferably 90% or more, more preferably 95% or more of unsaturated bonds in the “polyisoprene block” among the three polymer blocks contained in the SIS are hydrogenated.

The SIS may be a commercially available product. Examples of commercially available products of SIS include “Hibler 5127” (product name) (manufactured by Kuraray Co., Ltd.) and “Hibler 5215” (product name) (manufactured by Kuraray Co., Ltd).

The H-SIS may be a commercially available product. Examples of commercially available products of H-SIS include “Hibler 7125” (product name) (manufactured by Kuraray Co., Ltd.) and “Hibler 7311” (product name) (manufactured by Kuraray Co., Ltd).

The SBR-based adhesive contains the tackifier resin (B).

The tackifier resin (B) preferably has compatibility with the styrene-based thermoplastic elastomer (A). As the tackifier resin (B), rosin and a derivative thereof, a polyterpene resin and a hydride thereof, a terpene phenol resin and a hydride thereof, an aromatic modified terpene resin and a hydride thereof, a coumarone-indene resin, an aliphatic petroleum resin, an alicyclic petroleum resin and a hydride thereof, an aromatic petroleum resin and a hydride thereof, an aliphatic aromatic copolymer-based petroleum resin and a hydride thereof, an aliphatic aromatic copolymer-based petroleum resin, a dicyclopentadiene-based petroleum resin, and a hydride thereof are preferable from the viewpoint of having high compatibility with a polyisoprene block of SIS or H-SIS. Among them, as the tackifier resin (B), rosin and a derivative thereof, a polyterpene resin and a hydride thereof, an aliphatic petroleum resin, an alicyclic petroleum resin and a hydride thereof are preferable, rosin and a derivative thereof, an aliphatic petroleum resin, an alicyclic petroleum resin and a hydride thereof are further preferable, and a hydride of an alicyclic petroleum resin is particularly preferable.

The tackifier resin (B) may be a commercially available product. Examples of commercially available products of rosin and derivatives thereof include “PINECRYSTAL”, “SUPERESTER”, and “TAMANOL” (The above are manufactured by Arakawa Chemical Industries, Ltd.) under product names. Examples of commercially available products of the polyterpene resin, the terpene phenol resin, the aromatic modified terpene resin, and hydrides thereof include “YS Resin”, “YS Polyster”, and “Clearon” (The above are manufactured by Yasuhara Chemical Co., Ltd). Examples of commercially available products of an aliphatic petroleum resin, an alicyclic petroleum resin and a hydride thereof, an aromatic petroleum resin and a hydride thereof, an aliphatic aromatic copolymer-based petroleum resin, a dicyclopentadiene-based petroleum resin and a hydride thereof include “ARKON” (manufactured by Arakawa Chemical Industries, Ltd.), “HYREZ” (manufactured by Mitsui Chemicals, Inc.), “IMERB” (manufactured by Idemitsu Kosan Co., Ltd.), “QUINTON” (manufactured by Zeon Corporation), and “ESCOREZ” (manufactured by Tonex Corporation). The tackifier resin (B) can be used singly or in combination of two or more kinds thereof.

A blending amount of the tackifier resin (B) is 20 parts by mass to 150 parts by mass with respect to 100 parts by mass of the styrene-based thermoplastic elastomer (A). When the blending amount of the tackifier resin (B) is within the above range, the SBR-based adhesive is less likely to be sticky. Moreover, when the adhesive layer for original plate formed of the SBR-based adhesive is peeled off from the original plate, adhesive residues are less likely to occur.

The SBR-based adhesive may further contain other components.

Examples of other components include softeners and waxes.

The softener may be any material that can impart flexibility to the styrene-based thermoplastic elastomer (A), and examples thereof include polybutene, hydrogenated polybutene, unsaturated polybutene, aliphatic hydrocarbon, and acrylic polymer. An addition amount of the softener is preferably 20 parts by mass to 300 parts by mass, and more preferably 50 to 200 parts by mass, based on 100 parts by mass of the styrene-based thermoplastic elastomer (A).

The wax is a component capable of adjusting the hardness of the SBR-based adhesive.

As the wax, for example, a highly elastic material is preferable, and polyethylene wax, polypropylene wax, and the like are more preferable. An addition amount of the wax is preferably 20 parts by mass to 200 parts by mass, and more preferably 50 parts by mass to 100 parts by mass, based on 100 parts by mass of the styrene-based thermoplastic elastomer (A).

### (1.4.3.3) Si-Based Adhesive

The Si-based adhesive contains a silicone resin. Examples of the silicone resin include those obtained by partial dehydration condensation of an organopolysiloxane having a triorganosiloxane unit represented by R₃SiO_{0.5} (wherein R represents a substituted or unsubstituted monovalent hydrocarbon group) and a SiO₂ unit in the molecule with an organopolysiloxane having silanol groups at both terminals of the molecular chain.

The Si-based adhesive may be a commercially available product. Examples of commercially available products of the Si-based adhesive include “KR-101-10”, “KR-40-3326”, “KE-1820”, and “KR-105” (all manufactured by Shin-Etsu Chemical Co., Ltd).

### (1.4.4) Coating Method

A method of applying the coating composition is not particularly limited, and examples thereof include a method using a dispenser.

A thickness of the coating composition is preferably 0.1 mm to 4.5 mm, more preferably 0.1 mm to 3.5 mm, and still more preferably 0.2 mm to 2 mm.

### (1.4.5) Heating Method

A method of heating the coating composition is not particularly limited, and examples thereof include known methods.

A temperature at which the coating composition is heated is appropriately selected according to the boiling point of the solvent and the residual monomer, and is preferably 50° C. to 200° C., and more preferably 60° C. to 190° C.

By heating the coating composition, volatile compounds such as a solvent and a remaining monomer are removed from the adhesive layer.

In a case where the coating composition contains a crosslinking agent, the functional group of the alkyl (meth) acrylate ester copolymer and the crosslinking agent react with each other by heating to form a crosslinked structure in the adhesive layer precursor, so that a reaction product of the (meth) acrylic acid alkyl ester copolymer and the crosslinking agent is obtained. By this heating and drying, the adhesive layer precursor adheres to the surface of the pellicle frame 11, and the pellicle frame 11 and the adhesive layer precursor are integrated.

### (1.4.6) Plasma Nitriding Treatment

In the plasma nitriding treatment, the inner wall surface or the like of the adhesive layer precursor is exposed to plasma of a nitrogen gas or a nitrogen-containing gas. As a result, the adhesive layer 13 in which the inner wall surface or the like are modified is obtained. As a result, the amount of the outgas generated from the pellicle 10 decreases. In particular, the amount of outgassing caused by hydrocarbons is reduced. The cause of this is not clear, but it is presumed that nitrogen ions are adsorbed on the surface of the adhesive layer 13 to form a protective layer, thereby reducing the amount of outgas generated.

The plasma nitriding treatment is performed under the following treatment conditions using, for example, a plasma treatment device (Sputtering device for research and development “CFS-4EP-LL” manufactured by Shibaura Mechatronics Co., Ltd., type: load lock type).

### <Treatment Conditions of Plasma Nitriding Treatment>

Chamber ultimate vacuum: pressure <1e⁻³ Pa
Material gas: N₂ (G1 grade)
Gas flow rate: 21 sccm
Treatment pressure: 0.5 Pa
RF power: 100 W
Power application: sample side (reverse sputter mode)
Treatment time: 1 second to 90 seconds

The plasma nitriding treatment may be performed under the following treatment conditions using a plasma generator (manufactured by YOUTEC CO., LTD.) and a parallel plate type plasma CVD device.

### <Treatment Conditions of Plasma Nitriding Treatment>

Chamber ultimate vacuum: pressure <1e⁻³ Pa
Material gas: N₂ (G1 grade)
Gas flow rate: 100 sccm
Treatment pressure: 20 Pa
RF power: 100 W
Power application electrode size: Φ10 cm
Treatment time: 1 second to 90 seconds

### (1.4.7) Dehydration Treatment+Plasma Nitriding Treatment

The dehydration treatment may be performed before the plasma nitriding treatment. In the dehydration treatment, the pellicle coated with the coating composition can be disposed under a pressure of 5×10⁻⁴ Pa or less for 10 minutes or more, and then disposed under an inert gas atmosphere having a partial pressure of H₂O of 100 ppm or less and an atmospheric pressure of 90 kPa or more for 5 seconds or more. The cause of this is not clear, but it is presumed that when the dehydration treatment is performed before the plasma nitriding treatment, the adsorption of nitrogen ions to the surface of the adhesive layer 13 reaches the inside of the adhesive layer 13, so that the amount of outgas generation is more easily reduced.

### (1.4.8) EUV Irradiation Treatment

In the EUV irradiation treatment, the inner wall surface or the like of the adhesive layer precursor is irradiated with EUV. As a result, the adhesive layer 13 in which the inner wall surface or the like is modified is obtained. As a result, the amount of the outgas generated from the pellicle 10 decreases.

The EUV irradiation treatment can be performed, for example, in the same manner as a method described in Examples.

A dustproof adhesive layer may be formed on the inner peripheral wall S11C of the pellicle frame 11. In a case where the dustproof adhesive layer is formed, it is preferable to perform the surface treatment (plasma nitriding treatment or extreme ultraviolet irradiation treatment) in the same manner as the adhesive layer 13. The material of the dustproof adhesive layer may be the same as or different from the material of the adhesive layer 13.

### (1.4.9) Film Adhesive Layer Forming Step

A method of manufacturing the pellicle may further include a film adhesive layer forming step. An execution order of the film adhesive layer forming step may be before the adhesive layer forming step or after the adhesive layer forming step.

In the film adhesive layer forming step, the composition for a film adhesive layer is applied to the pellicle film side end surface S11A of the pellicle frame 11. As a result, a film adhesive layer is formed on the pellicle film side end surface S11A of the pellicle frame 11. As a result, the pellicle frame 11 can support the pellicle film 12 via the film adhesive layer.

The material of the composition for a film adhesive layer is not particularly limited, and examples thereof include those similar to those exemplified as the adhesive composition, known adhesives, and the like. The material of the composition for a film adhesive layer may be the same as or different from that of the adhesive composition.

A method of applying the composition for a film adhesive layer may be the same as the method exemplified as the method of applying the coating composition.

The composition for a film adhesive layer coated on the pellicle film side end surface S11A is preferably subjected to the surface treatment in the same manner as in the film adhesive layer forming step. As a result, the surface is modified, and a film adhesive layer in which the generation of outgas is suppressed is obtained.

A method of performing the surface treatment is appropriately selected according to the material of the composition for a film adhesive layer and the like, and examples thereof include the plasma nitriding treatment and the extreme ultraviolet irradiation treatment.

### (2) First Modification

### (2.1) Pellicle

A pellicle according to a first modification includes a pellicle frame, a pellicle film, and an adhesive layer. The pellicle film is supported by a pellicle film side end surface. The adhesive layer is provided on an adhesive layer side end surface. The at least one of the inner wall surface or the outer wall surface of the surface of the adhesive layer may satisfy the above Formula (2).

Since the pellicle according to the first modification has the above configuration, as described above, the generation of outgas can be suppressed.

The configuration of the pellicle according to the first modification is the same as that of the first embodiment except that the adhesive layer is different. The description of the first embodiment of the present disclosure can be incorporated into the description of the first modification of the present disclosure.

Hereinafter, a pellicle 10 according to a first modification will be described with reference to FIG. 1. Hereinafter, the description of the pellicle 10 according to the first modification similar to that of the pellicle 10 according to the first embodiment may be omitted.

The pellicle 10 according to the first modification includes a pellicle frame 11, a pellicle film 12, and an adhesive layer 13 as in the first embodiment.

### (2.1.1) Adhesive Layer

### (2.1.1.1) Rate of Change in CNO⁻

(2.1.1.1.1) [CNO⁻_{2 s}]

In the first modification, an inner wall surface S13A or the like satisfies the above Formula (2).

Since the inner wall surface S13A or the like satisfies Formula (2), generation of the outgas can be suppressed as described above.

An upper limit and a lower limit of ([CNO⁻_{2 s}]/[CNO⁻_{50 s}]), [CNO⁻_{2 s}], [CN⁻_{2 s}], and a method of making the inner wall surface S13A or the like satisfy Formula (2) is the same as that in the first embodiment.

(2.1.1.1.2) [CNO⁻_{6 s}]

In the first modification, the inner wall surface S13A or the like preferably satisfies the above Formula (4).

Since the inner wall surface S13A or the like satisfies the above Formula (4), the generation of the outgas can be suppressed as described above.

An upper limit and a lower limit of ([CNO⁻_{6 s}]/[CNO⁻_{50 s}]), and a method of making the inner wall surface S13A or the like satisfy Formula (4) is the same as that in the first embodiment.

### (2.1.1.2) Rate of Change in A

In the first modification, the inner wall surface S13A or the like preferably satisfies the above Formula (1).

Since the inner wall surface S13A or the like satisfies Formula (1), the outgas is less likely to occur as described above.

An upper limit and a lower limit of ([A_{2 s}]/[A_{50 s}]) are the same as those in the first embodiment.

In the first modification, the partial structure contained in the main agent component of the adhesive layer 13 analyzed by TOF-SIMS is preferably C₃H₃O⁺, C₇H₇⁺, or CH₃Si⁺ as in the first embodiment.

The partial structure contained in the main agent component of the adhesive layer 13 to be analyzed by TOF-SIMS can be determined in the same manner as in the first embodiment.

A method of making the inner wall surface S13A or the like satisfy Formula (1) is similar to that of the first embodiment.

In the first modification, similarly to the first embodiment, only one of the inner wall surface S13A and the outer wall surface S13B of the adhesive layer 13 may satisfy Formula (1), or the inner wall surface S13A and the outer wall surface S13B of the adhesive layer 13 may satisfy Formula (1), and it is preferable that the inner wall surface S13A and the outer wall surface S13B satisfy Formula (1).

### (2.1.1.3) Rate of Change in CN⁻

In the first modification, the inner wall surface S13A or the like preferably satisfies the above Formula (3).

The fact that the inner wall surface S13A or the like satisfies Formula (3) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit and a lower limit of ([CN⁻_{2 s}]/[CN⁻_{50 s}]), and the a method of making inner wall surface S13A or the like satisfy Formula (3) is the same as that in the first embodiment.

(2.1.1.4) Change Rate of C₃⁻

In the first modification, the inner wall surface S13A or the like preferably satisfies the above Formula (5).

Since the inner wall surface S13A or the like satisfies Formula (5), permeation of gas from the inside of the adhesive layer can be suppressed as described above.

An upper limit and a lower limit of ([C₃⁻₂s]/[C₃⁻₅₀s]), and a method of making the inner wall surface S13A or the like satisfy Formula (5) is the same as that in the first embodiment.

An upper limit of ([C₂HO⁻_{2 s}]/[C₂HO⁻_{50 s}]) is the same as that in the first embodiment.

### (2.1.1.5) Nitrogen Atom Concentration

In the first modification, the nitrogen atom concentration of the surface S13 such as the inner wall surface S13A is preferably 1.0 at % or more.

A preferred range of the nitrogen atom concentration and a method of measuring the nitrogen atom concentration are the same as those in the first embodiment.

### (2.1.1.6) Carbon Atom Concentration

In the first modification, the carbon atom concentration of the surface S13 such as the inner wall surface S13A is preferably 35 at % or more.

A preferred range of the carbon atom concentration and a method of measuring the carbon atom concentration are the same as those in the first embodiment.

### (2.1.2) Size of Adhesive Layer, etc.

In the first modification, a size of the adhesive layer 13, the pellicle frame 11, and the pellicle film 12 are the same as those of the first embodiment.

### (2.2) Exposure Original Plate

An exposure original plate according to the first modification includes an original plate and the pellicle 10 according to the first modification. The original plate has a pattern. The pellicle 10 according to the first modification is attached to the original plate on a surface on which the pattern is formed.

Since the exposure original plate according to the first modification includes the pellicle 10 according to the first modification, the same effect as that of the pellicle 10 according to the first modification is obtained.

An attachment method and the original plate according to the first modification are the same as those of the first embodiment.

### (2.3) Exposure Device

An exposure device according to the first modification includes an EUV light source, the exposure original plate according to the first modification, and an optical system. The EUV light source emits EUV light as exposure light. The optical system guides exposure light emitted from the EUV light source to the exposure original plate. The exposure original plate is disposed such that the exposure light emitted from the EUV light source passes through the pellicle film and is applied to the original plate.

Therefore, the exposure device according to the first modification has the same effect as that of the exposure original plate according to the first modification. Moreover, since the exposure device according to the first modification has the above-described configuration, in addition to being able to form a miniaturized pattern (for example, a line width of 32 nm or less), pattern exposure in which resolution defects due to foreign matter are reduced can be performed.

As the EUV light source, a known EUV light source can be used. As the optical system, a known optical system can be used.

### (2.4) Method of Manufacturing Pellicle Film

A method of manufacturing a pellicle film according to the first modification is the same as the method of manufacturing a pellicle film according to the first embodiment. Thereby, the pellicle 10 in which the inner wall surface S13A or the like satisfies Formula (2) is obtained.

### (3) Second Modification

### (3.1) Pellicle

A pellicle according to a second modification includes a pellicle frame, a pellicle film, and an adhesive layer. The pellicle film is supported by a pellicle film side end surface. The adhesive layer is provided on an adhesive layer side end surface. The at least one of the inner wall surface or the outer wall surface of the surface of the adhesive layer may satisfy the above formula (5).

Since the pellicle according to the second modification has the above configuration, as described above, the generation of the outgas can be suppressed. Moreover, the pellicle according to the second modification can suppress permeation of gas from the inside of the adhesive layer.

A configuration of the pellicle according to the second modification is the same as that of the first embodiment except that the adhesive layer is different. The description of the first embodiment of the present disclosure can be incorporated into the description of the second modification of the present disclosure.

Hereinafter, a pellicle 10 according to the second modification will be described with reference to FIG. 1. Hereinafter, the description of the pellicle 10 according to the second modification similar to that of the pellicle 10 according to the first embodiment may be omitted.

The pellicle 10 according to the second modification includes a pellicle frame 11, a pellicle film 12, and an adhesive layer 13 as in the first embodiment.

### (3.1.1) Adhesive Layer

(3.1.1.1) Change Rate of C₃⁻

In the second modification, the inner wall surface S13A or the like satisfies the above Formula (5).

Since the inner wall surface S13A or the like satisfies Formula (5), permeation of gas from the inside of the adhesive layer can be suppressed as described above.

An upper limit and a lower limit of ([C₃⁻₂s]/[C₃⁻₅₀s]), and a method of making the inner wall surface S13A or the like satisfy Formula (5) is the same as that in the first embodiment.

### (3.1.1.2) Rate of Change in A

In the second modification, the inner wall surface S13A or the like preferably satisfies the above Formula (1).

Since the inner wall surface S13A or the like satisfies Formula (1), the outgas is less likely to occur as described above.

An upper limit and a lower limit of ([A_{2 s}]/[A_{50 s}]) are the same as those in the first embodiment.

In the second modification, the partial structure contained in the main agent component of the adhesive layer 13 analyzed by TOF-SIMS is preferably C₃H₃O⁺, C₇H₇⁺, or CH₃Si⁺ as in the first embodiment.

The partial structure contained in the main agent component of the adhesive layer 13 to be analyzed by TOF-SIMS can be determined in the same manner as in the first embodiment.

A method of making the inner wall surface S13A or the like satisfy Formula (1) is similar to that of the first embodiment.

In the second modification, similarly to the first embodiment, only one of the inner wall surface S13A and the outer wall surface S13B of the adhesive layer 13 may satisfy Formula (1), or the inner wall surface S13A and the outer wall surface S13B of the adhesive layer 13 may satisfy Formula (1), and it is preferable that the inner wall surface S13A and the outer wall surface S13B satisfy Formula (1).

### (3.1.1.3) Rate of Change in CNO⁻

(3.1.1.3.1) [CNO⁻_{2 s}]

In the second modification, the inner wall surface S13A or the like satisfies the above Formula (2).

Since the inner wall surface S13A or the like satisfies Formula (2), generation of the outgas can be suppressed as described above.

An upper limit and a lower limit of ([CNO⁻_{2 s}]/[CNO⁻_{50 s}]), [CNO⁻_{2 s}], [CN⁻_{2 s}], and a method of making the inner wall surface S13A or the like satisfy Formula (2) is the same as that in the first embodiment.

(3.1.1.3.2) [CNO⁻_{6 s}]

In the second modification, the inner wall surface S13A or the like preferably satisfies the above Formula (4).

Since the inner wall surface S13A or the like satisfies the above Formula (4), the generation of the outgas can be suppressed as described above.

An upper limit and a lower limit of ([CNO⁻_{6 s}]/[CNO⁻_{50 s}]), and a method of making the inner wall surface S13A or the like satisfy Formula (4) is the same as that in the first embodiment.

### (3.1.1.4) Rate of Change in CN⁻

In the second modification, the inner wall surface S13A or the like preferably satisfies the above Formula (3).

The fact that the inner wall surface S13A or the like satisfies Formula (3) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit and a lower limit of ([CN⁻_{2 s}]/[CN⁻_{50 s}]), and a method of making the inner wall surface S13A or the like satisfy Formula (3) is the same as that in the first embodiment.

An upper limit of ([C₂HO⁻_{2 s}]/[C₂HO⁻_{50 s}]) is the same as that in the first embodiment.

### (3.1.1.5) Nitrogen Atom Concentration

In the second modification, the nitrogen atom concentration of the surface S13 such as the inner wall surface S13A is preferably 1.0 at % or more.

A preferred range of the nitrogen atom concentration and a method of measuring the nitrogen atom concentration are the same as those in the first embodiment.

### (3.1.1.6) Carbon Atom Concentration

In the second modification, the carbon atom concentration of the surface S13 such as the inner wall surface S13A is preferably 35 at % or more.

A preferred range of the carbon atom concentration and a method of measuring the carbon atom concentration are the same as those in the first embodiment.

### (3.1.2) Size of Adhesive Layer, etc.

In the second modification, a size of the adhesive layer 13, the pellicle frame 11, and the pellicle film 12 are the same as those of the first embodiment.

### (3.2) Exposure Original Plate

An exposure original plate according to the second modification includes an original plate and the pellicle 10 according to the second modification. The original plate has a pattern. The pellicle 10 according to the second modification is attached to the original plate on a surface on which the pattern is formed.

Since the exposure original plate according to the second modification includes the pellicle 10 according to the second modification, the same effect as that of the pellicle 10 according to the second modification is obtained.

An attachment method and the original plate according to the second modification are the same as those of the first embodiment.

### (3.3) Exposure Device

An exposure device according to the second modification includes an EUV light source, the exposure original plate according to the second modification, and an optical system. The EUV light source emits EUV light as exposure light. The optical system guides exposure light emitted from the EUV light source to the exposure original plate. The exposure original plate is disposed such that the exposure light emitted from the EUV light source passes through the pellicle film and is applied to the original plate.

Therefore, the exposure device according to the second modification has the same effect as that of the exposure original plate according to the second modification. Moreover, since the exposure device according to the second modification has the above-described configuration, in addition to being able to form a miniaturized pattern (for example, a line width of 32 nm or less), pattern exposure in which resolution defects due to foreign matter are reduced can be performed.

As the EUV light source, a known EUV light source can be used. As the optical system, a known optical system can be used.

### (3.4) Method of Manufacturing Pellicle Film

A method of manufacturing a pellicle film according to the second modification is the same as the method of manufacturing a pellicle film according to the first embodiment. Thereby, the pellicle 10 in which the inner wall surface S13A or the like satisfies Formula (5) is obtained.

### (4) Third Modification

### (4.1) Pellicle

A pellicle according to a third modification includes a pellicle frame, a pellicle film, and an adhesive layer. The pellicle film is supported by a pellicle film side end surface. The adhesive layer is provided on an adhesive layer side end surface. The at least one of the inner wall surface or the outer wall surface of the surface of the adhesive layer may satisfy the above Formula (3).

Since the pellicle according to the third modification has the above configuration, as described above, the generation of the outgas can be suppressed. Moreover, the pellicle according to the third modification can suppress permeation of gas from the inside of the adhesive layer.

A configuration of the pellicle according to the third modification is the same as that of the first embodiment except that the adhesive layer is different. The description of the first embodiment of the present disclosure can be incorporated into the description of the third modification of the present disclosure.

Hereinafter, a pellicle 10 according to the second modification will be described with reference to FIG. 1. Hereinafter, the description of the pellicle 10 according to the second modification similar to that of the pellicle 10 according to the first embodiment may be omitted.

The pellicle 10 according to the third modification includes a pellicle frame 11, a pellicle film 12, and an adhesive layer 13 as in the first embodiment.

### (4.1.1) Adhesive Layer

### (4.1.1.1) Rate of Change in CN⁻

In the third modification, the inner wall surface S13A or the like satisfies the above Formula (3).

The fact that the inner wall surface S13A or the like satisfies Formula (3) indicates that the surface layer of the adhesive layer 13 is modified to a compound derived from a nitrogen functional group, and the compound derived from the nitrogen functional group contributes to immobilization (high boiling point) of a hydrocarbon or serves as a gas barrier film that inhibits permeation of a gas from the inside of the adhesive layer 13. Therefore, the generation of the outgas can be suppressed.

An upper limit and a lower limit of ([CN⁻_{2 s}]/[CN⁻_{50 s}]), and a method of making the inner wall surface S13A or the like satisfy Formula (3) is the same as that in the first embodiment.

### (4.1.1.2) Rate of Change in A

In the third modification, the inner wall surface S13A or the like preferably satisfies the above Formula (1).

Since the inner wall surface S13A or the like satisfies Formula (1), the outgas is less likely to occur as described above.

An upper limit and a lower limit of ([A_{2 s}]/[A_{50 s}]) are the same as those in the first embodiment.

In the third modification, the partial structure contained in the main agent component of the adhesive layer 13 analyzed by TOF-SIMS is preferably C₃H₃O⁺, C₇H₇⁺, or CH₃Si⁺ as in the first embodiment.

The partial structure contained in the main agent component of the adhesive layer 13 to be analyzed by TOF-SIMS can be determined in the same manner as in the first embodiment.

A method of making the inner wall surface S13A or the like satisfy Formula (1) is similar to that of the first embodiment.

In the third modification, similarly to the first embodiment, only one of the inner wall surface S13A and the outer wall surface S13B of the adhesive layer 13 may satisfy Formula (1), or the inner wall surface S13A and the outer wall surface S13B of the adhesive layer 13 may satisfy Formula (1), and it is preferable that the inner wall surface S13A and the outer wall surface S13B satisfy Formula (1).

### (4.1.1.3) Rate of Change in CNO⁻

(4.1.1.3.1) [CNO⁻_{2 s}]

In the third modification, the inner wall surface S13A or the like satisfies the above Formula (2).

Since the inner wall surface S13A or the like satisfies Formula (2), generation of the outgas can be suppressed as described above.

An upper limit and a lower limit of ([CNO⁻_{2 s}]/[CNO⁻_{50 s}]), [CNO⁻_{2 s}], [CN⁻_{2 s}], and a method of making the inner wall surface S13A or the like satisfy Formula (2) is the same as that in the first embodiment.

(4.1.1.3.2) [CNO⁻_{6 s}]

In the third modification, the inner wall surface S13A or the like preferably satisfies the above Formula (4).

Since the inner wall surface S13A or the like satisfies the above Formula (4), the generation of the outgas can be suppressed as described above.

An upper limit and a lower limit of ([CNO⁻_{6 s}]/[CNO⁻_{50 s}]), and a method of making the inner wall surface S13A or the like satisfy Formula (4) is the same as that in the first embodiment.

(4.1.1.5) Change Rate of C₃⁻

In the third modification, the inner wall surface S13A or the like preferably satisfies the above Formula (5).

Since the inner wall surface S13A or the like satisfies Formula (5), permeation of gas from the inside of the adhesive layer can be suppressed as described above.

An upper limit and a lower limit of ([C₃⁻₂s]/[C₃⁻₅₀s]), and a method of making the inner wall surface S13A or the like satisfy Formula (5) is the same as that in the first embodiment.

An upper limit of ([C₂HO⁻_{2 s}]/[C₂HO⁻_{50 s}]) is the same as that in the first embodiment.

### (4.1.1.6) Nitrogen Atom Concentration

In the third modification, the nitrogen atom concentration of the surface S13 such as the inner wall surface S13A is preferably 1.0 at % or more.

A preferred range of the nitrogen atom concentration and a method of measuring the nitrogen atom concentration are the same as those in the first embodiment.

### (4.1.1.7) Carbon Atom Concentration

In the third modification, the carbon atom concentration of the surface S13 such as the inner wall surface S13A is preferably 35 at % or more.

A preferred range of the carbon atom concentration and a method of measuring the carbon atom concentration are the same as those in the first embodiment.

### (4.1.2) Size of Adhesive Layer, etc.

In the third modification, a size of the adhesive layer 13, the pellicle frame 11, and the pellicle film 12 are the same as those of the first embodiment.

### (4.2) Exposure Original Plate

An exposure original plate according to the third modification includes an original plate and the pellicle 10 according to the third modification. The original plate has a pattern. The pellicle 10 according to the third modification is attached to the original plate on a surface on which the pattern is formed.

Since the exposure original plate according to the third modification includes the pellicle 10 according to the third modification, the same effect as that of the pellicle 10 according to the third modification is obtained.

An attachment method and the original plate according to the third modification are the same as those of the first embodiment.

### (4.3) Exposure Device

An exposure device according to the third modification includes an EUV light source, the exposure original plate according to the third modification, and an optical system. The EUV light source emits EUV light as exposure light. The optical system guides exposure light emitted from the EUV light source to the exposure original plate. The exposure original plate is disposed such that the exposure light emitted from the EUV light source passes through the pellicle film and is applied to the original plate.

Therefore, the exposure device according to the third modification has the same effect as that of the exposure original plate according to the third modification. Moreover, since the exposure device according to the third modification has the above-described configuration, in addition to being able to form a miniaturized pattern (for example, a line width of 32 nm or less), pattern exposure in which resolution defects due to foreign matter are reduced can be performed.

As the EUV light source, a known EUV light source can be used. As the optical system, a known optical system can be used.

### (4.4) Method of Manufacturing Pellicle Film

A method of manufacturing a pellicle film according to the third modification is the same as the method of manufacturing a pellicle film according to the first embodiment. Thereby, the pellicle 10 in which the inner wall surface S13A or the like satisfies Formula (5) is obtained.

The embodiment of the present disclosure have been described above with reference to the drawing. However, the present disclosure is not limited to the above embodiment, and can be implemented in various aspects without departing from the gist of the present disclosure. For easy understanding, the drawing schematically illustrate each constituent element mainly, and the thickness, length, number, and the like of each illustrated constituent element are different from actual ones for convenience of drawing. The material, shape, size, and the like of each component shown in the above embodiment are merely examples, and are not particularly limited, and various modifications can be made without substantially departing from the effects of the present disclosure.

### EXAMPLES

Hereinafter, the present disclosure will be described in more detail with reference to Examples, but the invention of the present disclosure is not limited only to these Examples.

### [1] Preparation of Adhesive

In the following Examples and Comparative Examples, an Ac-based adhesive 1, an Ac-based adhesive 2, and an SBR-based adhesive produced as follows were used as the coating composition.

### [1.1] Production of Ac-Based Adhesive 1

As a raw material of the Ac-based adhesive 1, the following various components were used.

### <(Meth) Acrylic Acid Alkyl Ester Monomer>

EA: ethyl acrylate
MMA: methyl methacrylate

### <Functional Group-Containing Monomer>

HEMA: 2-hydroxyethyl methacrylate
GMA: glycidyl methacrylate

### <Crosslinking Agent>

“RIKACID MH-700G” manufactured by New Japan Chemical Co., Ltd.

### <Polymerization Solvent>

propyl acetate

### <Polymerization Initiator>

AIBN: 2,2′-azobisisobutyronitrile (10 hour half-life temperature: 65° C.)

### <Catalyst>

Amine-based catalyst: “U-CAT SA-102” (chemical formula: octylate of (1,8-diazabicyclo-(5.4.0) undecene-7) manufactured by San-Apro Ltd.

A reaction vessel equipped with a stirrer, a thermometer, a reflux condenser, a dropping device, and a nitrogen introduction pipe was prepared. A polymerization solvent (180 parts by mass) was placed in a reaction vessel, and a mixture (423.4 parts by mass) of EA/MMA/HEMA/GMA/polymerization initiator was charged therein at a mass ratio of 378/21/12.6/8.4/3.4. In a nitrogen atmosphere, this reaction solution was reacted at 85° C. for 6 hours and further at 95° C. for 2 hours to obtain an acrylic copolymer solution having a nonvolatile content (main agent) concentration of 70 mass %.

A crosslinking agent (0.28 parts by mass) and a catalyst (0.93 parts by mass) were added to the obtained acrylic copolymer solution (143 parts by mass), and the mixture was stirred and mixed to obtain a coating composition of the Ac-based adhesive 1.

### [Measurement of Weight Average Molecular Weight (Mw) and Number Average Molecular Weight (Mn) of (Meth) Acrylic Acid Alkyl Ester Copolymer]

Each condition of GPC used for measuring the weight average molecular weight (Mw) and the number average molecular weight (Mn) of the (meth) acrylic acid alkyl ester copolymer is as follows.

### <Conditions of GPC>

Pump: “LC-10AD” manufactured by Shimadzu Corporation
Oven: “CT020A” manufactured by Shimadzu Corporation
Detector: “RI-101” manufactured by Showa Denko K.K.
Data processing software: “Empower 3” manufactured by Waters Corporation
GPC column: “PLgel MIXED-B” (7.5×300 mm) manufactured by Agilent Technologies Corporation×2 columns
Column temperature: 40° C.
Elution solvent: tetrahydrofuran
Flow rate: 1.0 mL/min
Sample concentration: 0.1% (w/v)
Sample injection amount: 100 μL
Standard substance: monodisperse polystyrene

### [1.2] Production of Ac-Based Adhesive 2

As a raw material of the Ac-based adhesive 2, the following various components were used.

### <(Meth) Acrylic Acid Alkyl Ester Monomer>

EA: ethyl acrylate

### <Functional Group-Containing Monomer>

4-HBA: 4-hydroxybutyl acrylate
HEMA: 2-hydroxyethyl methacrylate
GMA: glycidyl methacrylate

### <Crosslinking Agent>

“RIKACID MH-700G” manufactured by New Japan Chemical Co., Ltd.

### <Polymerization Solvent>

propyl acetate

### <Polymerization Initiator>

AIBN: 2,2′-azobisisobutyronitrile (10 hour half-life temperature: 60° C.)

### <Catalyst>

Amine-based catalyst: “U-CAT SA-102” (chemical formula: octylate of (1,8-diazabicyclo-(5.4.0) undecene-7) manufactured by San-Apro Ltd.

A reaction vessel equipped with a stirrer, a thermometer, a reflux condenser, a dropping device, and a nitrogen introduction pipe was prepared. A polymerization solvent (180 parts by mass) was placed in a reaction vessel, and a mixture (423.4 parts by mass) of EA/4-HBA/HEMA/GMA/polymerization initiator was charged therein at a mass ratio of 378/12. 6/21/8.4/3.4. In a nitrogen atmosphere, this reaction solution was reacted at 85° C. for 6 hours and further at 95° C. for 2 hours to obtain an acrylic copolymer solution having a nonvolatile content (main agent) concentration of 70 mass % (weight average molecular weight: 119,000, number average molecular weight (Mn): 30,600, Mw/Mn: 3.9).

A crosslinking agent (0.28 parts by mass) and a catalyst (0.93 parts by mass) were added to the obtained acrylic copolymer solution (143 parts by mass), and the mixture was stirred and mixed to obtain a coating composition of the Ac-based adhesive 2.

### [1.3] Preparation of SBR-Based Adhesive

An SBR-based adhesive was prepared as follows.

As a raw material of the SBR-based adhesive, the following various components were used.

### <Thermoplastic Elastomer (A)>

H-SIS: styrene-hydrogenated isoprene-styrene block copolymer (product name “Hibler 7125” (manufactured by Kuraray Co., Ltd.))

### <Tackifier Resin (B)>

Hydroxide of alicyclic petroleum resin: C9 hydrogenated petroleum resin (product name “ARKON P-100” (manufactured by Arakawa Chemical Industries, Ltd.))

### <Softener>

Paraffinic mineral oil (product name “NEOVAC MR-200” (manufactured by MORESCO))

100 parts by mass of the thermoplastic elastomer (A), 100 parts by mass of the tackifier resin (B), and 60 parts by mass of the softener were mixed so that the total amount was 48 g to obtain a raw material mixture. The obtained raw material mixture was charged into Labo Plastomill (manufactured by Toyo Seiki Seisaku-sho, Ltd., content: 60 mL), and then sealed. The mixture was kneaded at 200° C. and 100 rpm for 20 minutes to obtain a massive coating composition. About 10 g of the coating composition in a lump form was put into a heating tank (temperature in the tank: 200° C.) and melted. As a result, a coating composition of the SBR-based adhesive was obtained.

### [1.4] Silicone-Based Adhesive

A silicone rubber sheet (“T-809” (model number at the time of acquisition) manufactured by Tigers Polymer Co., Ltd.) was prepared as a silicone-based adhesive.

### [2] Example 1

A dispersion liquid in which single-walled carbon nanotubes (manufactured by MEIJO NANO CARBON CO., LTD.) were dispersed in a solvent was prepared. The dispersion liquid was spin-coated on a silicon substrate and dried to form an ultrathin film (hereinafter, also referred to as a “CNT film”) of carbon nanotubes on the silicon substrate.

Next, the silicon substrate was gently immersed in a water tank filled with pure water to liberate the CNT film as a single film from the silicon substrate, the CNT film was floated on a water surface, and the CNT film was scooped up in a dummy frame (outer dimension 171 mm×138.5 mm, inner dimension 163 mm×130.5 mm, thickness 2.0 mm) slightly larger than an outer dimension of the pellicle frame and dried.

An aluminum frame (outer dimension 151 mm×118.5 mm, inner dimension 143 mm×110.5 mm, height 2.0 mm) was prepared as the pellicle frame.

As the coating composition, a coating composition of the Ac-based adhesive 1 was used.

The coating composition of the Ac-based adhesive 1 was applied to the adhesive layer side end surface of the pellicle frame, heated and dried at 100° C., and heated at 120° C. to cure the coating composition, thereby obtaining an adhesive layer precursor (adhesive composition). The inner wall surface and the outer wall surface of the adhesive layer precursor were subjected to an EUV irradiation treatment under the same conditions as the EUV irradiation treatment described later. Thus, the adhesive layer was formed.

In the CNT film scooped up by the dummy frame, a part without wrinkles was transferred to a pellicle frame slightly smaller than the dummy frame, so that a pellicle film without wrinkles was disposed on the pellicle film side end surface of the pellicle frame. Thereby, the pellicle was obtained.

The depth direction analysis of the obtained pellicle by TOF-SIMS and the analysis of the outgas generation amount were substituted with an EUV irradiation treated product described later.

### [2.1] Production of EUV Irradiation Treated Product

The EUV irradiation treated product was prepared as follows.

An 8-inch size silicon wafer (Hereinafter, the silicon substrate is also referred to as a “silicon substrate”.) was prepared.

A coating composition of the Ac-based adhesive 1 was applied onto a silicon substrate, dried by heating at 100° C., and cured by heating at 120° C. to form an adhesive layer. As a result, a product before EUV irradiation treatment was obtained. A size of the adhesive layer was 3 mm in width, 6 mm in length, and 0.2 mm in thickness.

### [2.2] EUV Irradiation Treatment and Analysis of Outgas Generation Amount

Using an EUV irradiation device (Facility name: NewSUBARU synchrotron radiation facility, Beamline: “BL-9C_H-ch”, Operation: University of Hyogo, Advanced Industrial Science and Technology Research), Quadrupole mass spectrometer: “M-200” manufactured by Canon Anelva Co., Ltd.), the product before EUV irradiation treatment was subjected to the EUV irradiation treatment as follows.

### [2.2.1] EUV Irradiation Treatment

The product before EUV irradiation treatment was inserted into an exposure chamber of an EUV irradiation device.

The product before EUV irradiation treatment was irradiated with EUV (wavelength: 13.5 nm). The irradiation intensity of EUV was 0.3 W/cm², and the beam size was 2×0.5 mm. The EUV irradiation time was 10 minutes. An area of a region irradiated with EUV (Hereinafter, it is also referred to as an “EUV irradiation treated region”.) on the surface of the adhesive layer was 0.2 mm×2.4 mm. As a result, the EUV irradiation treated product was obtained.

[2.2.2] Analysis of Outgas Generation Amount (without Glass Substrate)

An amount of outgas generated (no glass substrate) in each of an aqueous system, a volatile hydrocarbon-based system, and a nonvolatile hydrocarbon-based system of the EUV irradiation treated product was obtained as follows.

### [2.2.2.1] Partial Pressure Measurement of Chamber Background

First, in a state where the EUV treated product was not placed in a sample holder in the exposure chamber (that is, an empty state), a first ion current value for each measurement mass when the degree of vacuum was sufficiently increased (when the pressure in the chamber was 1×10⁻⁶ Pa or less) was measured. Hereinafter, the pressure when the degree of vacuum is sufficiently increased is also referred to as “first pressure”. The partial pressure (BG1 to BG200) for each measurement mass in the background was calculated by distributing the first pressure to the first ion current values of the measurement mass 1 to 200. For example, the partial pressure BG1 indicates a partial pressure of the chamber background having a molecular weight of 1 (m/z=1), and the partial pressure BG200 indicates a partial pressure of the chamber background having a molecular weight of 200 (m/z=200).

Specifically, a partial pressure (BGn) of a molecular weight n (m/z=n) was calculated by the following formula. n represents a natural number of 1 to 200.

Partial pressure (BGn)=first pressure×(first ion current value with molecular weight n/(sum of first ion current values with molecular weight of 1 to 200))

[2.2.2.2] Partial Pressure Measurement when EUV-treated Product is Disposed

Next, in a state where the EUV treated product was placed in the sample holder in the exposure chamber, the EUV treated product was irradiated with EUV light having an EUV irradiation intensity of 0.3 W/cm² and a beam size of 2×0.5 mm. A second pressure was measured while irradiating the EUV-treated product with the EUV light at the time when 10 minutes elapsed from the time when the irradiation of the EUV light was started. At the same time, the second ion current value for each measurement mass was measured using a quadrupole mass meter connected to the exposure chamber. The second pressure was converted from a second ion current value (corresponding to a mass number) corresponding to the measurement mass to a partial pressure (A1 to A200) corresponding to the measurement mass when the EUV-treated product was disposed. For example, the partial pressure A1 indicates a partial pressure of m/z=1 (corresponding to a molecular weight of 1), and the partial pressure A200 indicates a partial pressure of m/z=200 (corresponding to a molecular weight of 200).

Specifically, a partial pressure (An) of m/z=n (corresponding to a molecular weight n) was calculated by the following formula. n represents a natural number of 1 to 200.

Partial pressure (An)=second pressure×(second ion current value of m/z=n/(sum of second ion current values corresponding to m/z=1 to 200))

### [2.2.2.3] Calculation of Net Partial Pressure

For each measurement mass, the partial pressure (BG1 to BG200) of the chamber background was subtracted from the partial pressure (A1 to A200) when the EUV-treated product was disposed, and a net partial pressure (S1 to S200) for each measurement mass was calculated.

Specifically, the net partial pressure (Sn) of m/z=n was calculated by the following formula. n represents a natural number of 1 to 200.

Net partial pressure (Sn)=partial pressure (An)−partial pressure (BGn)

### [2.2.2.4] Method of Measuring Chamber Effective Exhaust Speed V

Nitrogen of 0.1 sccm (=0.17 Pa·L/s) was introduced into the vacuum chamber, and pump exhaust was performed. The pressure when the pressure in the vacuum chamber was stable (that is, when the fluctuation of the pressure in the vacuum chamber is small) was 6e⁻⁴ Pa. The chamber effective exhaust speed obtained from this value was estimated to be about 3×10² L/sec (=0.17/6e⁻⁴ L/sec).

[2.2.2.5] Calculation of Outgas Generation Amount (without Glass Substrate)

Using the net partial pressure (Sn) and the chamber effective exhaust speed (V) as the chamber effective exhaust speed V (L/sec), the outgas generation amount for each measurement mass was calculated from a relational expression of Sn×V (Pa·L/sec).

From the gas generation amount for each measurement mass, a ratio of each of an aqueous system (16 amu, 17 amu, 18 amu), a volatile hydrocarbon-based system (45 amu to 100 amu), and a nonvolatile hydrocarbon-based system (101 amu to 200 amu) was calculated. By integrating the calculated ratios, each of the amount of outgas generated in the water system, the amount of outgas generated in the volatile hydrocarbon system, and the amount of outgas generated in the nonvolatile hydrocarbon system was calculated.

Analysis results of the outgas generation amount (without glass substrate) are shown in Table 1.

### [2.2.3] Depth Direction Analysis by TOF-SIMS

Depth direction analysis of a predetermined region of the adhesive layer was performed using a time-of-flight secondary ion mass spectrometer (manufactured by ULVAC-PHI, Inc., product number: “PHI nanoTOF II”, component: Ar-GCIB). In Example 1, a predetermined region indicates a part of the EUV irradiation treated region.

Specifically, first, a predetermined region was analyzed under the following analysis conditions.

Next, under the following etching conditions, a predetermined region was irradiated with a sputter ion gun (Ar-GCIB) for 2 seconds, and under the following analysis conditions, an operation (Hereinafter, it is also referred to as a “first operation”.) of analyzing a deep portion formed in the predetermined region was performed. Thereafter, the first operation was repeated nine times. The irradiation time of the sputter ion gun (Ar-GCIB) with respect to the predetermined area was 20 seconds in total.

Next, under the following etching conditions, a predetermined region was irradiated with the sputter ion gun (Ar-GCIB) for 5 seconds, and under the following analysis conditions, an operation (Hereinafter, the operation is also referred to as a “second operation”.) of analyzing a deep portion formed in the predetermined region was performed. Thereafter, the second operation was repeated nine times. The irradiation time of the sputter ion gun (Ar-GCIB) with respect to the predetermined area was 70 seconds in total.

Table 1 shows analysis results of the first deep portion formed by irradiating the predetermined area with the sputter ion gun (Ar-GCIB) for a total of 2 seconds, analysis results of the second deep portion formed by irradiating the predetermined area with the sputter ion gun (Ar-GCIB) for a total of 50 seconds, and analysis results of the third deep portion formed by irradiating the predetermined area with the sputter ion gun (Ar-GCIB) for a total of 6 seconds.

A depth from the surface of the first deep portion calculated from the etching rate was about 16 nm. A depth from the surface of the second deep portion calculated from the etching rate was about 400 nm. A depth from the surface of the third deep portion calculated from the etching rate was about 48 nm.

### <Analysis Conditions by TOF-SIMS>

Primary ion source: Bi₃⁺⁺
Polarity of secondary ion: positive and negative
Analysis area: 100 μm×100 μm

### <Etching Condition by Sputter Ion Gun (Ar-GCIB)>

Beam voltage: 20 kV
Beam current: 20 nA (Sample Current: about 20 nA)
Raster range: 600 μm×600 μm

### [2.2.4] Analysis of Carbon Atom Concentration

The carbon atom concentration of the EUV irradiation treated product was measured by the above-described method. The measurement results are shown in Table 1.

### [3] Comparative Example 1

A pellicle was obtained in the same manner as in Example 1 except that the inner wall surface and the outer wall surface of the adhesive layer precursor were not subjected to the EUV irradiation treatment.

For the analysis of the obtained pellicle in the depth direction by TOF-SIMS and the analysis of the outgas generation amount, a product before EUV irradiation treatment prepared in the same manner as in Example 1 was used instead.

A product before EUV irradiation treatment was obtained in the same manner as in Example 1.

For the product before EUV irradiation treatment, a predetermined region of the adhesive layer was analyzed in the depth direction in the same manner as in Example 1. In Comparative Example 1, the predetermined region indicates a part of the surface of the adhesive layer.

Next, with respect to the product before EUV irradiation treatment, the analysis of the amount of outgas generation (without glass substrate) and the analysis of the carbon atom concentration were performed in the same manner as in Example 1 except that the EUV was not irradiated.

The analysis results are shown in Table 1.

### [4] Example 2

A pellicle was obtained in the same manner as in Example 1 except that the Ac-based adhesive 2 was used instead of the Ac-based adhesive 1 as the adhesive composition, and the inner wall surface and the outer wall surface of the adhesive layer precursor were subjected to a plasma nitriding treatment described later instead of the EUV irradiation treatment.

The depth direction analysis of the obtained pellicle by TOF-SIMS and the analysis of the outgas generation amount were substituted with a plasma nitrided product described later.

### [4.1] Plasma-Nitrided Product

The plasma nitrided product was prepared as follows.

As the pellicle frame, the following stainless steel pellicle frame was used.

The pellicle frame was a rectangular cylindrical object. An outer dimension of the pellicle frame was 149 mm×122 mm. A frame height of the pellicle frame (corresponding to reference sign L3 in FIG. 1) was 2 mm. A frame width (corresponding to reference sign L4 in FIG. 1) of the pellicle frame was 4 mm.

The coating composition of the Ac-based adhesive 2 was applied to the adhesive layer side end surface of the pellicle frame, heated and dried at 100° C., and heated at 120° C. to cure the coating composition, thereby forming an adhesive layer. As a result, a product before plasma nitriding treatment was obtained.

An adhesive agent protecting film (Hereinafter, it is also referred to as a “liner”.) was attached to an adhesive portion (corresponding to sign S13C in FIG. 1) of the adhesive layer to the original plate. The inner wall surface and the outer wall surface were exposed.

For TOF-SIMS measurement, a part of the liner in a range of 5 mm in length and the entire width of the portion of the liner adhered to the original plate to which the liner was attached was removed, and a part of the portion of the adhesive layer adhered to the original plate (Hereinafter, also referred to as an “adhesive flat portion”.) was exposed.

### [4.1.1] Plasma Nitriding Treatment

The adhesive flat part was subjected to the plasma nitriding treatment using a plasma treatment device (sputtering device for research and development “CFS-4EP-LL” manufactured by Shibaura Mechatronics Co., Ltd., type: load lock type).

Specifically, the product before plasma nitriding treatment was fixed to a metal holder and set in a load lock chamber of the plasma treatment device. The inside of the load lock chamber was vacuumed to set the degree of vacuum in the load lock chamber to 1.0×10⁻³ Pa or less. The product before plasma nitriding treatment was conveyed from the inside of the load lock chamber into the plasma treatment chamber. The inside of the plasma treatment chamber was evacuated, and the degree of vacuum in the plasma treatment chamber was set to 2.0×10⁻⁴ Pa or less. Nitrogen gas was introduced into the plasma treatment chamber to adjust the pressure in the plasma treatment chamber.

RF power was applied to expose an exposed portion of the product before plasma nitriding treatment, which was not covered with the liner, to nitrogen gas plasma under the following treatment conditions to obtain a plasma nitrided product. The inside of the plasma treatment chamber was evacuated, and the plasma nitrided product was carried out to the load lock chamber. A vent operation was performed with nitrogen gas in the load lock chamber to release the gas to the atmosphere, and the plasma nitrided product was taken out from the load lock chamber.

### <Treatment Conditions of Plasma Nitriding Treatment>

Material gas: N₂ (G1 grade)
Gas flow rate: 21 sccm
Treatment pressure: 0.5 Pa
RF power: 100 W (Reverse sputter mode: applied to the sample holder)
Treatment time: 60 seconds

### [4.2] Depth Direction Analysis by TOF-SIMS

A predetermined region of the adhesive layer of the plasma nitrided product was analyzed in the depth direction in the same manner as in Example 1. In Example 2, the predetermined region indicates an adhesive flat portion. Note that, in the analysis by TOF-SIMS of Example 2, a sample obtained by cutting out the adhesive flat portion together with the pellicle frame from the plasma nitrided product was analyzed.

The analysis results are shown in Table 1.

[4.3] Analysis of Outgas Generation Amount (without Glass Substrate)

Using a quadrupole mass spectrometer (“APL200” manufactured by Apex Corporation, a quadrupole mass spectrometer (QMS): “M201QA-TDM” manufactured by Canon Anelva Corporation, software: “Quad Vision 3”), the amount of outgas generated (without glass substrate) containing H₂O (m/z=16 to 18) and hydrocarbon (CxHy) (m/z=45 to 200) was analyzed.

The outgas generation amount (without glass substrate) was obtained by subtracting the second outgas generation amount as a background from the first outgas generation amount. The first outgas generation amount indicates a gas generation amount obtained in a state where a plasma nitrided product is disposed in the vacuum chamber. The second outgas generation amount indicates a gas generation amount obtained in a state where the plasma nitrided product is not disposed in the vacuum chamber.

### [4.3.1] Measurement of First Outgas Generation Amount

The liner was peeled off from the plasma nitrided product to obtain a measurement product. The measurement product was placed on an 8 inch size silicon wafer set in the load lock chamber of a quadrupole mass spectrometer. The inside of the load lock chamber was roughened with a rotary pump. Using a turbo molecular pump, the inside of the load lock chamber was evacuated for 10 minutes, and the degree of vacuum in the load lock chamber was set to 1.0×10⁻³ Pa or less. The measurement product was conveyed from the inside of the load lock chamber into the vacuum chamber of the quadrupole mass spectrometer evacuated to 1.0×10⁻⁶ Pa or less using the turbo molecular pump through a gate valve.

The gas components in the vacuum chamber were analyzed with the quadrupole mass spectrometer 15 minutes after the conveyance was completed. As a result, a current value (A) of each “m/z” of the outgas was obtained. The heater current of the filament was 2.0 mA, and the SEM (secondary electron multiplier) voltage of the quadrupole mass spectrometer was 1,500 V. A temperature of the substrate stage in the vacuum chamber was 28° C.

The pressure of each component (m/z) of the outgas was calculated as follows.

The pressure obtained by multiplying the pressure (Pa) in the vacuum chamber at the time of analysis of the quadrupole mass spectrometer by a current value ratio of each component (m/z) was defined as the pressure (Pa) of each component (m/z) of the outgas. The current value ratio of each component (m/z) indicates the ratio of the current value (A) of each component (m/z) to the integral value of the current value (A) of “m/z”=1 to 200.

The exhaust speed in the vacuum chamber was calculated as follows.

A value of the exhaust speed was calculated from the value obtained by dividing the N₂ flow rate by the pressure (Pa) when a conveyance valve with the vacuum chamber was opened and the pressure in the vacuum chamber was stabilized (that is, when the fluctuation of the pressure in the vacuum chamber is small,). The N₂ flow rate was obtained by multiplying the N₂ pressure increase rate (Pa/sec) when a slow leak Vent valve was slightly opened in a state where the exhaust valve of the load lock chamber and the conveyance valve of the vacuum chamber were first closed by the capacity (10 L) of the load lock chamber.

The calculation result of the exhaust speed was 180 L/sec.

A first outgas generation amount (0.01 mbar·L/sec) of each component (m/z) was calculated by obtaining the product of the pressure (Pa) of each component (m/z) of the outgas and the exhaust speed (L/sec) in the vacuum chamber and dividing the product by 100 as shown in the following formula.

First outgas generation amount (mbar·L/sec) of each component (m/z)={pressure (Pa) in vacuum chamber at the time of analysis of quadrupole mass spectrometer/100 (mbar)}×{current value (A) for specific component (m/z)/E current value (m/z=1 to 200) (A)}×exhaust speed (180 L/sec)

As described above, the first outgas generation amount of H₂O (m/z=16 to 18), the first outgas generation amount of hydrocarbon (CxHy) (m/z=45 to 100), and the first outgas generation amount of hydrocarbon (CxHy) (m/z=101 to 200) in the plasma nitrided product were calculated.

### [4.3.2] Measurement of Second Out Gas Generation Amount

A second outgas generation amount of H₂O (m/z=16 to 18), a second outgas generation amount of hydrocarbon (CxHy) (m/z=45 to 100), and a second outgas generation amount of hydrocarbon (CxHy) (m/z=101 to 200) were calculated in the same manner as in <Measurement of First Outgas Generation Amount> except that the measurement product was not placed on an 8-inch size silicon wafer set in the load lock chamber of the quadrupole mass spectrometer.

[4.3.3] Calculation of Outgas Generation Amount (without Glass Substrate)

For each of H₂O (m/z=16 to 18), hydrocarbon (CxHy) (m/z=45 to 100), and hydrocarbon (CxHy) (m/z=101 to 200), a value obtained by subtracting the second gas generation amount from the first outgas generation amount was multiplied by the exhaust speed to obtain the outgas generation amount (without glass substrate).

The analysis results are shown in Table 1.

### [4.4] Analysis of Carbon Atom Concentration

The carbon atom concentration of the plasma nitrided product was measured by the above-described method. The measurement results are shown in Table 1.

### [5] Example 3

A pellicle was obtained in the same manner as in Example 2 except that the dehydration treatment was performed before the plasma nitriding treatment. A film for protecting an adhesive (Hereinafter, it is also referred to as a “liner”.) having a width (2.5 mm) slightly smaller than a width of the adhesive portion (corresponding to sign S13C in FIG. 1) of the adhesive layer to the original plate was attached. The inner wall surface and the outer wall surface were exposed. In order to perform XPS analysis and TOF-SIMS analysis, a part of the liner in a range of 5 mm in length and the entire width of the portion of the liner adhered to the original plate to which the liner was attached was removed, and a part of the portion of the adhesive layer adhered to the original plate (Hereinafter, also referred to as an “adhesive flat portion”.) was exposed to obtain a product before dehydration treatment.

The product before dehydration treatment was fixed to a metal holder and set in the load lock chamber of the plasma treatment device. The inside of the load lock chamber was evacuated, and the degree of vacuum in the load lock chamber was set to 5.0×10⁻⁴ Pa or less and the product was stored for 1 hour. Thereafter, nitrogen gas was sealed in the load lock chamber so as to reach atmospheric pressure, and the product was stored for 5 minutes. The above vacuuming and nitrogen gas sealing were performed twice to obtain a dehydrated product.

### [5.1.2] Plasma Nitriding Treatment

Then, with the dehydrated product remaining set in the vacuum chamber, vacuuming was performed, and the degree of vacuum in the plasma treatment chamber was set to 2.0×10⁻⁴ Pa or less and held for 2 hours. Nitrogen gas was introduced into the plasma treatment chamber for 5 minutes to adjust the pressure in the plasma treatment chamber.

The adhesive layer of the dehydrated product was exposed to nitrogen gas plasma under the following treatment conditions to obtain a plasma nitrided product. The inside of the plasma treatment chamber was evacuated, and the plasma nitrided product was carried out to the load lock chamber. A vent operation was performed with nitrogen gas in the load lock chamber to release the gas to the atmosphere, and the plasma nitrided product was taken out from the load lock chamber.

### <Treatment Conditions of Plasma Nitriding Treatment>

Gas: N₂,
Gas flow rate: 100 sccm
Treatment pressure: 20 Pa
RF power (13.56 MHz): 100 W
Treatment time: 60 seconds

### [5.2] Analysis

For the plasma nitrided product, the depth direction analysis of a predetermined region of the adhesive layer, the analysis of the outgas generation amount (no glass substrate), and the analysis of the carbon atom concentration were performed in the same manner as in Example 2. In Example 3, the predetermined region indicates a part of the surface of the adhesive layer. The analysis results are shown in Table 1.

### [6] Comparative Example 2

A pellicle was obtained in the same manner as in Example 2 except that the inner wall surface and the outer wall surface of the adhesive layer precursor were not subjected to the plasma nitriding treatment.

The depth direction analysis of the obtained pellicle by TOF-SIMS and the analysis of the outgas generation amount were substituted with a product before plasma nitriding treatment described later.

A product before plasma nitriding treatment was obtained in the same manner as in Example 2 except that the plasma nitriding treatment was not performed.

For the product before plasma nitriding treatment, the depth direction analysis of a predetermined region of the adhesive layer, the analysis of the outgas generation amount (no glass substrate), and the analysis of the carbon atom concentration were performed in the same manner as in Example 2. In Comparative Example 2, the predetermined region indicates a part of the surface of the adhesive layer. The analysis results are shown in Table 1.

### [7] Example 4

A pellicle was obtained in the same manner as in Example 2 except that an SBR-based adhesive was used instead of the Ac-based adhesive 2 as an adhesive resin composition.

The depth direction analysis of the obtained pellicle by TOF-SIMS and the analysis of the outgas generation amount were substituted with a plasma nitrided product described later.

The plasma nitriding treatment, the depth direction analysis by TOF-SIMS, the analysis of the outgas generation amount (no glass substrate), and the analysis of the carbon atom concentration were performed in the same manner as in Example 2 except that the coating composition of the SBR-based adhesive was used instead of the coating composition of the Ac-based adhesive 2. The analysis results are shown in Table 1.

### [8] Comparative Example 3

A pellicle was obtained in the same manner as in Example 4 except that the inner wall surface and the outer wall surface of the adhesive layer precursor were not subjected to the plasma nitriding treatment.

The depth direction analysis of the obtained pellicle by TOF-SIMS and the analysis of the outgas generation amount were substituted with a product before plasma nitriding treatment described later.

A product before plasma nitriding treatment was obtained in the same manner as in Example 4 except that the plasma nitriding treatment was not performed.

For the product before plasma nitriding treatment, the depth direction analysis of a predetermined region of the adhesive layer, the analysis of the outgas generation amount (without glass substrate), and the analysis of the carbon atom concentration were performed in the same manner as in Example 4. In Comparative Example 3, the predetermined region indicates a part of the surface of the adhesive layer. The analysis results are shown in Table 1.

### [9] Example 5

A pellicle was obtained in the same manner as in Example 2 except that a silicone-based adhesive was used as the adhesive resin composition in place of the Ac-based adhesive 2.

The depth direction analysis of the obtained pellicle by TOF-SIMS and the analysis of the outgas generation amount were substituted with a plasma nitrided product described later.

The plasma nitriding treatment, the depth direction analysis by TOF-SIMS, the analysis of the outgas generation amount (no glass substrate), and the analysis of the carbon atom concentration were performed in the same manner as in Example 2 except that the coating composition of the silicone-based adhesive was used instead of the coating composition of the Ac-based adhesive 2. The analysis results are shown in Table 1.

### [10] Example 6

A pellicle was obtained in the same manner as in Example 3 except that a silicone-based adhesive was used as the adhesive resin composition in place of the Ac-based adhesive 2.

The depth direction analysis of the obtained pellicle by TOF-SIMS and the analysis of the outgas generation amount were substituted with a double-treated product described later.

The plasma nitriding treatment, the depth direction analysis by TOF-SIMS, the analysis of the outgas generation amount (no glass substrate), and the analysis of the carbon atom concentration were performed in the same manner as in Example 3 except that the coating composition of the silicone-based adhesive was used instead of the coating composition of the Ac-based adhesive 2. The analysis results are shown in Table 1.

### [11] Comparative Example 4

A pellicle was obtained in the same manner as in Comparative Example 2 except that a silicone-based adhesive was used as the adhesive resin composition in place of the Ac-based adhesive 2.

The depth direction analysis of the obtained pellicle by TOF-SIMS and the analysis of the outgas generation amount were substituted with a product before plasma nitriding treatment described later.

A product before plasma nitriding treatment was obtained in the same manner as in Comparative Example 2 except that the coating composition of the silicone-based adhesive was used instead of the coating composition of the Ac-based adhesive 2.

For the product before plasma nitriding treatment, the depth direction analysis of a predetermined region of the adhesive layer, the analysis of the outgas generation amount (no glass substrate), and the analysis of the carbon atom concentration were performed in the same manner as in Comparative Example 2. The analysis results are shown in Table 1.

TABLE 1

| | | | Comparative | | | Comparative |
|---|---|---|---|---|---|---|
| | | Example 1 | Example 1 | Example 2 | Example 3 | Example 2 |
| Type of adhesive | | Ac-based | Ac-based | Ac-based | Ac-based | Ac-based |
| | | adhesive 1 | adhesive 1 | adhesive 2 | adhesive 2 | adhesive 2 |
| Surface treatment | | EUV | — | Plasma | Dehydration | — |
| | | irradiation | | nitriding | treatment + | |
| | | treatment | | treatment | plasma | |
| | | | | | nitriding | |
| | | | | | treatment | |
| Depth | [C₃H₃O₂⁻_{2 s}]/[C₃H₃O₂⁻_{50 s}] | 0.46 | 0.92 | 0.85 | 0.06 | 0.98 |
| direction | [C₂HO⁻_{2 s}]/[C₂HO⁻_{50 s}] | 0.65 | 0.99 | 0.92 | 0.38 | 1.00 |
| analysis (TOF- | [C₃H₃O⁺_{2 s}]/[C₃H₃O⁺_{50 s}] | 0.50 | 1.00 | 0.85 | 0.42 | 0.99 |
| SIMS) | [C₂H₅⁺_{2 s}]/[C₂H₅⁺_{50 s}] | 0.46 | 1.01 | 0.90 | 0.20 | 1.01 |
| | [C₄H₇⁺_{2 s}]/[C₄H₇⁺_{50 s}] | 0.27 | 1.02 | 1.04 | 0.92 | 1.02 |
| | [C₇H₇⁺_{2 s}]/[C₇H₇⁺_{50 s}] | 0.17 | 1.02 | 0.91 | 1.35 | 0.99 |
| | [CH₃Si⁺_{2 s}]/[CH₃Si⁺_{50 s}] | — | — | — | — | — |
| | [CNO⁻_{1 s}]/[CNO⁻_{50 s}] | — | — | 6.88 | 14.02 | 1.20 |
| | [CNO⁻_{2 s}]/[CNO⁻_{50 s}] | 0.98 | 1.50 | 3.10 | 7.83 | 1.18 |
| | [CNO⁻_{6 s}]/[CNO⁻_{50 s}] | 0.93 | 1.46 | 1.14 | 3.21 | 1.19 |
| | [CN⁻_{1 s}]/[CN⁻_{50 s}] | — | — | 6.66 | 7.20 | 1.10 |
| | [CN⁻_{2 s}]/[CN⁻_{50 s}] | 1.30 | 1.06 | 2.7 | 3.26 | 1.02 |
| | [CN⁻_{6 s}]/[CN⁻_{50 s}] | 1.30 | 1.04 | 1.07 | 1.52 | 1.01 |
| | [C₃⁻_{2 s}]/[C₃⁻_{50 s}] | 1.40 | 0.96 | 1.03 | 2.45 | 0.99 |
| | [C₄⁻_{2 s}]/[C₄⁻_{50 s}] | 1.57 | 1.07 | 1.09 | 4.01 | 1.09 |
| | [CN⁻_{1 s}] | — | — | 0.043 | 0.042 | 0.004 |
| | [CNO⁻_{1 s}] | — | — | 0.004 | 0.010 | 0.000 |
| | [CN⁻_{2 s}] | 0.020 | 0.005 | 0.018 | 0.019 | 0.0033 |
| | [CNO⁻_{2 s}] | 0.002 | 0.001 | 0.0019 | 0.006 | 0.0005 |
| | [C₇H₇⁺_{2 s}] | 0.002 | 0.011 | 0.010 | 0.014 | 0.011 |
| | [CH₃Si⁺_{2 s}] | 0.000 | 0.000 | 0.000 | 0.001 | 0.000 |
| | [C₃H₉Si⁺_{2 s}] | 0.000 | 0.012 | 0.007 | 0.001 | 0.010 |
| | [CH₃Si⁺_{2 s}] + [C₃H₉Si⁺_{2 s}] | 0.001 | 0.012 | 0.007 | 0.001 | 0.010 |
| | [C₃H₃O⁺_{2 s}] | 0.004 | 0.046 | 0.040 | 0.020 | 0.052 |
| | [C₇H₇⁺_{50 s}] | 0.005 | 0.011 | 0.011 | 0.010 | 0.011 |
| | [CH₃Si⁺_{50 s}] | 0.001 | 0.000 | 0.000 | 0.000 | 0.000 |
| | [C₃H₉Si⁺_{50 s}] | 0.000 | 0.011 | 0.008 | 0.010 | 0.009 |
| | [CH₃Si⁺_{50 s}] + [C₃H₉Si⁺_{50 s}] | 0.001 | 0.011 | 0.008 | 0.011 | 0.009 |
| | [C₃H₃O⁺_{50 s}] | 0.008 | 0.046 | 0.047 | 0.048 | 0.052 |
| Surface | C (at %) | 76.0 | 71.5 | 71.5 | 56.1 | 75.2 |
| composition | N (at %) | 0.0 | 0.7 | 3.7 | 8.0 | 0.0 |
| Analysis of | H₂O(16-18) (mba · L/sec) | 9.0 × 10⁻⁸ | 1.0 × 10⁻⁴ | 4.9 × 10⁻⁶ | 2.9 × 10⁻⁵ | 5.7 × 10⁻⁵ |
| outgas | CₓH_{y}(45-100) (mbar · L/sec) | 7.5 × 10⁻⁹ | 2.4 × 10⁻⁸ | 6.2 × 10⁻⁹ | 7.6 × 10⁻⁹ | 2.0 × 10⁻⁸ |
| generation | CₓH_{y}(101-200) (mbar · L/sec) | 8.9 × 10⁻¹⁰ | 1.3 × 10⁻⁹ | 9.0 × 10⁻¹⁰ | 3.8 × 10⁻¹⁰ | 1.2 × 10⁻⁹ |
| amount (QMS) | | | | | | |
| | | | Comparative | | | Comparative |
| | | Example 4 | Example 3 | Example 5 | Example 6 | Example 4 |
| Type of adhesive | | SBR-based | SBR-based | Silicone-based | Silicone-based | Silicone-based |
| | | adhesive | adhesive | adhesive | adhesive | adhesive |
| Surface treatment | | Plasma | — | Plasma | Dehydration | — |
| | | nitriding | | nitriding | treatment + | |
| | | treatment | | treatment | plasma | |
| | | | | | nitriding | |
| | | | | | treatment | |
| Depth | [C₃H₃O₂⁻_{2 s}]/[C₃H₃O₂⁻_{50 s}] | 1.41 | 2.14 | 1.26 | 1.38 | 1.43 |
| direction | [C₂HO⁻_{2 s}]/[C₂HO⁻_{50 s}] | 1.56 | 1.66 | 1.23 | 1.31 | 1.27 |
| analysis (TOF- | [C₃H₃O⁺_{2 s}]/[C₃H₃O⁺_{50 s}] | 0.94 | 1.58 | 0.96 | 0.95 | 1.96 |
| SIMS) | [C₂H₅⁺_{2 s}]/[C₂H₅⁺_{50 s}] | 1.21 | 1.02 | 1.04 | 0.97 | 1.23 |
| | [C₄H₇⁺_{2 s}]/[C₄H₇⁺_{50 s}] | 0.90 | 0.98 | 1.29 | 1.25 | 1.51 |
| | [C₇H₇⁺_{2 s}]/[C₇H₇⁺_{50 s}] | 0.82 | 0.98 | 2.71 | 2.37 | 1.02 |
| | [CH₃Si⁺_{2 s}]/[CH₃Si⁺_{50 s}] | — | — | 0.59 | 0.60 | 1.05 |
| | [CNO⁻_{1 s}]/[CNO⁻_{50 s}] | 380.2 | 90.10 | 2.26 | 2.20 | 1.70 |
| | [CNO⁻_{2 s}]/[CNO⁻_{50 s}] | 235.90 | 29.23 | 1.42 | 1.34 | 1.48 |
| | [CNO⁻_{6 s}]/[CNO⁻_{50 s}] | 45.64 | 15.92 | 1.08 | 0.96 | 1.23 |
| | [CN⁻_{1 s}]/[CN⁻_{50 s}] | 27.3 | 68.48 | 8.19 | 13.38 | 1.57 |
| | [CN⁻_{2 s}]/[CN⁻_{50 s}] | 19.1 | 24.13 | 5.30 | 7.49 | 1.47 |
| | [CN⁻_{6 s}]/[CN⁻_{50 s}] | 2.5 | 14.41 | 1.86 | 2.07 | 1.25 |
| | [C₃⁻_{2 s}]/[C₃⁻_{50 s}] | 0.63 | 0.92 | 1.21 | 1.19 | 1.08 |
| | [C₄⁻_{2 s}]/[C₄⁻_{50 s}] | 0.73 | 0.90 | 1.14 | 1.41 | 1.02 |
| | [CN⁻_{1 s}] | 0.076 | 0.0044 | 0.0049 | 0.008 | 0.001 |
| | [CNO⁻_{1 s}] | 0.005 | 0.002 | 0.001 | 0.001 | 0.001 |
| | [CN⁻_{2 s}] | 0.053 | 0.0015 | 0.0031 | 0.005 | 0.00103 |
| | [CNO⁻_{2 s}] | 0.003 | 0.0005 | 0.000 | 0.001 | 0.0006 |
| | [C₇H₇⁺_{2 s}] | 0.013 | 0.018 | 0.000 | 0.000 | 0.000 |
| | [CH₃Si⁺_{2 s}] | 0.000 | 0.000 | 0.008 | 0.008 | 0.013 |
| | [C₃H₉Si⁺_{2 s}] | 0.000 | 0.000 | 0.140 | 0.136 | 0.146 |
| | [CH₃Si⁺_{2 s}] + [C₃H₉Si⁺_{2 s}] | 0.000 | 0.000 | 0.148 | 0.144 | 0.159 |
| | [C₃H₃O⁺_{2 s}] | 0.000 | 0.000 | 0.000 | 0.000 | 0.000 |
| | [C₇H₇⁺_{50 s}] | 0.016 | 0.018 | 0.000 | 0.000 | 0.000 |
| | [CH₃Si⁺_{50 s}] | 0.000 | 0.000 | 0.013 | 0.013 | 0.013 |
| | [C₃H₉Si⁺_{50 s}] | 0.000 | 0.000 | 0.112 | 0.120 | 0.134 |
| | [CH₃Si⁺_{50 s}] + [C₃H₉Si⁺_{50 s}] | 0.000 | 0.000 | 0.125 | 0.133 | 0.147 |
| | [C₃H₃O⁺_{50 s}] | 0.000 | 0.000 | 0.000 | 0.000 | 0.000 |
| Surface | C (at %) | 73.5 | 81.8 | 37.5 | 36.2 | 52.5 |
| composition | N (at %) | 10.2 | 0.0 | 2.0 | 2.6 | 0.0 |
| Analysis of | H₂O(16-18) (mba · L/sec) | 2.6 × 10⁻⁶ | 3.4 × 10⁻⁶ | 7.6 × 10⁻⁴ | 2.1 × 10⁻⁴ | 9.5 × 10⁻⁴ |
| outgas | CₓH_{y}(45-100) (mbar · L/sec) | 4.2 × 10⁻⁹ | 2.6 × 10⁻⁷ | 3.4 × 10⁻⁷ | 1.6 × 10⁻⁸ | 1.0 × 10⁻⁵ |
| generation | CₓH_{y}(101-200) (mbar · L/sec) | 3.7 × 10⁻¹⁰ | 2.1 × 10⁻⁸ | 1.4 × 10⁻⁸ | 6.3 × 10⁻¹⁰ | 2.6 × 10⁻⁶ |
| amount (QMS) | | | | | | |

In Table 1, the secondary ion in the item of the depth direction analysis (TOF-SIMS) is a component having a relatively high intensity or a partial structure having a large change in normalized intensity among a plurality of secondary ions analyzed by TOF-SIMS in the first deep portion and the second deep portion.

In Table 1, the “Analysis of outgas generation amount (QMS)” indicates the analysis result of the outgas generation amount by the quadrupole mass spectrometer.

In Table 1, [CNO⁻₁ₛ] indicates a normalized intensity of CNO⁻ obtained by analyzing a fourth deep portion of the adhesive layer 13 having a fourth depth from the surface S13 by TOF-SIMS using the primary ion gun. The fourth depth is formed by irradiating a 600 μm square area of the surface with the sputter ion gun (Ar-GCIB) for a total of 1 second.

In Table 1, [CN⁻₁ₛ] indicates a normalized intensity of CN⁻ obtained by analyzing the fourth deep portion by TOF-SIMS using the primary ion gun.

When Examples and Comparative Examples were compared with each other, it was found that by performing the EUV irradiation treatment or the plasma nitriding treatment, the main agent component of the surface layer of the adhesive layer as a source of the outgas was reduced, and the outgas could be reduced.

Comparison between Examples subjected to the plasma nitriding treatment and Comparative Examples not subjected to the plasma nitriding treatment showed that [CNO⁻_{2 s}] and [CN⁻_{2 s}] on the surface layer of the adhesive layer increased, and the outgas could be reduced.

This is expected to be because the gas barrier film was modified to a compound derived from a nitrogen functional group to inhibit gas permeation from the inside of the adhesive layer.

When Examples subjected to the EUV irradiation treatment and Comparative Examples not subjected to the EUV irradiation treatment were compared, it was found that [C₃⁻] of the surface layer of the adhesive layer was increased, and the outgas could be reduced. This is expected to be because the surface layer of the adhesive layer was carbonized to suppress the generation of the outgas.

### [12] Example 7

A pellicle was obtained in the same manner as in Example 2 except that a part of the liner was not removed for TOF-SIMS measurement, and the adhesive layer was attached to quartz glass after the liner of the plasma nitrided product was removed. The analysis of the outgas generation amount (with a glass substrate) was performed in the same manner as in Example 2 for a bonded product obtained by removing the liner of a plasma nitrided product and then bonding an adhesive layer to the quartz glass.

### [12.1] Measurement of First Outgas Generation Amount

The bonded product was placed on an 8-inch silicon wafer set in the load lock chamber of the quadrupole mass spectrometer to obtain a combined product. The inside of the load lock chamber was roughened with a rotary pump. Further, the inside of the load lock chamber was evacuated for 10 minutes using a turbo molecular pump, and the degree of vacuum in the load lock chamber was set to 1.0×10⁻³ Pa or less. The combined product was conveyed from the inside of the load lock chamber into the vacuum chamber of the quadrupole mass spectrometer evacuated to 1.0×10⁻⁶ Pa or less using a turbo molecular pump through a gate valve.

The gas components in the vacuum chamber were analyzed with the quadrupole mass spectrometer at 15 minutes, 30 minutes, 1 hour, 2 hours, and 5 hours after the end of conveyance. As a result, a current value (A) of each “m/z” of the outgas was obtained. The heater current of the filament was 2.0 mA, and the SEM (secondary electron multiplier) voltage of the quadrupole mass spectrometer was 1,500 V. A temperature of the substrate stage in the vacuum chamber was 28° C.

### [12.2] Measurement of Second Outgas Generation Amount

The first outgas generation amount and the second outgas generation amount of H₂O (m/z=16 to 18), the first outgas generation amount and the second outgas generation amount of hydrocarbon (CxHy) (m/z=45 to 100), and the first outgas generation amount and the second outgas generation amount of hydrocarbon (CxHy) (m/z=101 to 200) in the plasma nitrided product were calculated in the same manner as in (Analysis of Outgas Generation Amount (without Glass Substrate)).

[12.3] Calculation of Outgas Generation Amount (with Glass Substrate)

For each of H₂O (m/z=16 to 18), hydrocarbon (CxHy) (m/z=45 to 100), and hydrocarbon (CxHy) (m/z=101 to 200), a value obtained by subtracting the second gas generation amount from the first outgas generation amount was multiplied by the exhaust speed to obtain an outgas generation amount (with glass substrate). The analysis results are shown in Table 2.

### [13] Example 8

A pellicle was obtained in the same manner as in Example 3 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

### [14] Comparative Example 5

A pellicle was obtained in the same manner as in Comparative Example 2 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

### [15] Example 9

A pellicle was obtained in the same manner as in Example 4 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

### [16] Comparative Example 6

A pellicle was obtained in the same manner as in Comparative Example 3 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass.

### [17] Example 10

A pellicle was obtained in the same manner as in Example 5 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

### [18] Example 11

A pellicle was obtained in the same manner as in Example 6 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

### [19] Comparative Example 7

A pellicle was obtained in the same manner as in Comparative Example 6 except that a part of the liner was not removed for TOF-SIMS measurement, and the adhesive layer was attached to the quartz glass after the liner of the plasma nitrided product was removed. The analysis of the outgas generation amount (with a glass substrate) was performed in the same manner as in Example 7 for the bonded product obtained by removing the liner of the plasma nitrided product and then bonding an adhesive layer to the quartz glass. The analysis results are shown in Table 2.

TABLE 2

| | | | | Comparative | | Comparative | | | Comparative |
|---|---|---|---|---|---|---|---|---|---|
| | | Example 7 | Example 8 | Example 5 | Example 9 | Example 6 | Example 10 | Example 11 | Example 7 |
| Type of adhesive | | Ac-based | Ac-based | Ac-based | SBR-based | SBR-based | Silicone- | Silicone-based | Silicone- |
| | | adhesive 2 | adhesive 2 | adhesive 2 | adhesive | adhesive | based | adhesive | based |
| | | | | | | | adhesive | | adhesive |
| Surface treatment | | Plasma | Dehydration | — | Plasma | — | Plasma | Dehydration | — |
| | | nitriding | treatment + | | nitriding | | nitriding | treatment + | |
| | | treatment | plasma | | treatment | | treatment | plasma | |
| | | | nitriding | | | | | nitriding | |
| | | | treatment | | | | | treatment | |
| 15 | H₂O (16-18) [mbar · L/sec] | 1.8 × 10⁻⁴ | 2.1 × 10⁻⁴ | 2.4 × 10⁻⁴ | 3.5 × 10⁻⁶ | 3.6 × 10⁻⁶ | 6.2 × 10⁻⁴ | 2.2 × 10⁻⁴ | 1.2 × 10⁻³ |
| min | CₓH_{y} (45-100) [mbar · L/sec] | 2.6 × 10⁻⁸ | 3.0 × 10⁻⁸ | 3.9 × 10⁻⁸ | 1.6 × 10⁻⁸ | 9.7 × 10⁻⁸ | 4.5 × 10⁻⁸ | 4.8 × 10⁻⁸ | 5.3 × 10⁻⁷ |
| | CₓH_{y} (101-200) [mbar · L/sec] | 9.9 × 10⁻¹⁰ | 1.1 × 10⁻⁹ | 1.2 × 10⁻⁹ | 1.5 × 10⁻⁹ | 4.0 × 10⁻⁹ | 2.1 × 10⁻⁹ | 1.6 × 10⁻⁹ | 5.3 × 10⁻⁸ |
| 30 | H₂O (16-18) [mbar · L/sec] | 1.5 × 10⁻⁴ | 1.4 × 10⁻⁴ | 2.0 × 10⁻⁴ | 2.8 × 10⁻⁶ | 4.0 × 10⁻⁶ | 5.0 × 10⁻⁴ | 1.8 × 10⁻⁴ | 8.8 × 10⁻⁴ |
| min | CₓH_{y} (45-100) [mbar · L/sec] | 2.4 × 10⁻⁸ | 2.4 × 10⁻⁸ | 3.4 × 10⁻⁸ | 1.7 × 10⁻⁹ | 1.0 × 10⁻⁷ | 3.6 × 10⁻⁸ | 4.7 × 10⁻⁸ | 4.5 × 10⁻⁷ |
| | CₓH_{y} (101-200) [mbar · L/sec] | 9.4 × 10⁻¹⁰ | 9.2 × 10⁻¹⁰ | 1.2 × 10⁻⁹ | 1.2 × 10⁻¹⁰ | 6.8 × 10⁻⁹ | 1.3 × 10⁻⁹ | 1.6 × 10⁻⁹ | 5.0 × 10⁻⁸ |
| 1 h | H₂O (16-18) [mbar · L/sec] | 1.1 × 10⁻⁴ | 7.5 × 10⁻⁵ | 1.5 × 10⁻⁴ | 1.8 × 10⁻⁶ | 2.2 × 10⁻⁶ | 3.5 × 10⁻⁴ | 1.4 × 10⁻⁴ | 6.2 × 10⁻⁴ |
| | CₓH_{y} (45-100) [mbar · L/sec] | 2.8 × 10⁻⁸ | 2.2 × 10⁻⁸ | 3.0 × 10⁻⁸ | 1.7 × 10⁻⁹ | 9.4 × 10⁻⁸ | 2.5 × 10⁻⁸ | 4.3 × 10⁻⁸ | 3.7 × 10⁻⁷ |
| | CₓH_{y} (101-200) [mbar · L/sec] | 9.6 × 10⁻¹⁰ | 7.6 × 10⁻¹⁰ | 1.1 × 10⁻⁹ | 1.8 × 10⁻¹⁰ | 7.2 × 10⁻⁹ | 9.4 × 10⁻¹⁰ | 1.3 × 10⁻⁹ | 4.9 × 10⁻⁸ |
| 2 h | H₂O (16-18) [mbar · L/sec] | 6.9 × 10⁻⁵ | 2.7 × 10⁻⁵ | 9.6 × 10⁻⁵ | 7.5 × 10⁻⁷ | 1.3 × 10⁻⁶ | 1.8 × 10⁻⁴ | 9.9 × 10⁻⁵ | 3.1 × 10⁻⁴ |
| | CₓH_{y} (45-100) [mbar · L/sec] | 2.0 × 10⁻⁸ | 1.0 × 10⁻⁸ | 2.3 × 10⁻⁸ | 8.9 × 10⁻¹⁰ | 1.2 × 10⁻⁷ | 1.8 × 10⁻⁸ | 3.0 × 10⁻⁸ | 2.5 × 10⁻⁷ |
| | CₓH_{y} (101-200) [mbar · L/sec] | 8.2 × 10⁻¹⁰ | 6.1 × 10⁻¹⁰ | 9.3 × 10⁻¹⁰ | 1.4 × 10⁻¹⁰ | 8.8 × 10⁻⁹ | 7.8 × 10⁻¹⁰ | 6.6 × 10⁻¹⁰ | 2.9 × 10⁻⁸ |
| 5 h | H₂O (16-18) mbar · L/sec] | 1.6 × 10⁻⁵ | 1.8 × 10⁻⁶ | 3.2 × 10⁻⁵ | 1.7 × 10⁻⁷ | 6.4 × 10⁻⁷ | 8.9 × 10⁻⁵ | 5.1 × 10⁻⁵ | 1.3 × 10⁻⁴ |
| | CₓH_{y} (45-100) [mbar · L/sec] | 7.9 × 10⁻⁹ | 2.6 × 10⁻⁹ | 1.0 × 10⁻⁸ | 3.7 × 10⁻¹⁰ | 9.2 × 10⁻⁸ | 4.0 × 10⁻⁹ | 9.4 × 10⁻⁹ | 2.5 × 10⁻⁷ |
| | CₓH_{y} (101-200) [mbar · L/sec] | 7.6 × 10⁻¹⁰ | 4.1 × 10⁻¹⁰ | 9.6 × 10⁻¹⁰ | 1.3 × 10⁻¹⁰ | 6.8 × 10⁻⁹ | 4.1 × 10⁻¹¹ | 3.3 × 10⁻¹⁰ | 2.3 × 10⁻⁸ |

In Table 2, each of “15 min”, “30 min”, “1 h”, “2 h”, and “5 h” indicates the timing (that is, the time elapsed from the time point at which the object to be measured was transported into the vacuum chamber) at which the component analysis was performed.

When Examples and Comparative Examples were compared with each other, it was found that by performing the EUV irradiation treatment or the plasma nitriding treatment, the main agent component of the surface layer of the adhesive layer as a source of the outgas was reduced, and the outgas could be reduced.

Comparison between Examples subjected to the plasma nitriding treatment and Comparative Examples not subjected to the plasma nitriding treatment showed that [CNO⁻_{2 s}] and [CN⁻_{2 s}] on the surface layer of the adhesive layer increased, and the outgas could be reduced. This is expected to be because the gas barrier film was modified to a compound derived from a nitrogen functional group to inhibit gas permeation from the inside of the adhesive layer.

When Examples subjected to the EUV irradiation treatment and Comparative Examples not subjected to the EUV irradiation treatment were compared, it was found that [C₃⁻] of the surface layer of the adhesive layer was increased, and the outgas could be reduced. This is expected to be because the surface layer of the adhesive layer was carbonized to suppress the generation of the outgas.

The materials of the adhesive layers of Example 1 and Comparative Example 1 are the same (that is, the Ac-based adhesive 1).

In Example 1 and Comparative Example 1, [C₃H₃O⁺_{50 s}] was 0.005 or more. That is, the material of the adhesive layer 13 of Example 1 and Comparative Example 1 is determined to contain the Ac-based adhesive.

The adhesive layer of Example 1 satisfied the following Formula (1a) related to volatile hydrocarbon (CxHy: m/z=45 to 100). Therefore, an amount of outgassing from the volatile hydrocarbon (CxHy: m/z=45 to 100) of Example 1 was about 7.5×10⁻⁹ [mbar·L/sec].

$$[ {C}_{3} {H}_{3} {{O}^{+}}_{2 s} ] / [ {C}_{3} {H}_{3} {{O}^{+}}_{50 s} ] ) \leq 0.97 \qquad Formula ( 1 a )$$

In Formula (1a), [C₃H₃O⁺_{2 s}] represents a normalized intensity of C₃H₃O⁺ obtained by analyzing the first deep portion by TOF-SIMS. [C₃H₃O⁺_{50 s}] represents a normalized intensity of C₃H₃O⁺ obtained by analyzing the second deep portion by TOF-SIMS.

On the other hand, the adhesive layer of Comparative Example 1 did not satisfy Formula (1a). Therefore, an amount of outgas generated with respect to the volatile hydrocarbon (CxHy: m/z=45 to 100) in Comparative Example 1 was 2.4×10⁻⁸ [mbar·L/sec], which was higher than that in Example 1.

From the above, in Example 1, it was found that when the adhesive layer satisfies Formula (1a), outgas is less likely to be generated.

The materials of the adhesive layers of Example 2, Example 3, and Comparative Example 2 are the same (that is, the Ac-based adhesive 2).

In Example 2, Example 3, and Comparative Example 2, [C₃H₃O⁺_{50 s}] was 0.005 or more. That is, the material of the adhesive layer 13 of Example 2, Example 3, and Comparative Example 2 is determined to contain the Ac-based adhesive.

The adhesive layers of Examples 2 and 3 satisfied Formula (1a). Therefore, an amount of outgassing from the volatile hydrocarbons (CxHy: m/z=45 to 100) generated in Examples 2 and 3 was 7.6×10⁻⁹ [mbar·L/sec] or less.

On the other hand, the adhesive layer of Comparative Example 2 did not satisfy Formula (1a). Therefore, an amount of outgas generated with respect to the volatile hydrocarbon (CxHy: m/z=45 to 100) in Comparative Example 2 was 2.0×10⁻⁸ [mbar·L/sec], which was higher than that in Examples 2 and 3.

From the above, it has been found that Examples 2 and 3 are related to the fact that outgas is hardly generated when the adhesive layer satisfies Formula (1a).

The materials of the adhesive layers of Example 4 and Comparative Example 3 are the same (that is, the SBR-based adhesive).

In Example 4 and Comparative Example 3, [C₃H₃O⁺_{50 s}] was less than 0.005, and ([CH₃Si⁺_{50 s}]+[C₃H₉Si⁺_{50 s}]) was less than 0.050. That is, it is determined that the material of the adhesive layer 13 of Example 4 and Comparative Example 3 contains neither the Ac-based adhesive nor the Si-based adhesive.

The adhesive layer of Example 4 satisfied the following Formula (1b). Therefore, an amount of outgassing from the volatile hydrocarbon (CxHy: m/z=45 to 100) of Example 4 was about 4.2×10⁻⁹ [mbar·L/sec].

$$[ {C}_{7} {{{H}_{7}}^{+}}_{2 s} ] / [ {C}_{7} {{{H}_{7}}^{+}}_{50 s} ] ) \leq 0.97 \qquad Formula ( 1 b )$$

In Formula (1b), [C₇H₇⁺_{2 s}] represents a normalized intensity of C₇H₇⁺ obtained by analyzing the first deep portion by TOF-SIMS. [C₇H₇⁺_{50 s}] represents a normalized intensity of C₇H₇⁺ obtained by analyzing the second deep portion by TOF-SIMS.

On the other hand, the adhesive layer of Comparative Example 3 did not satisfy Formula (1b). Therefore, the outgas generation amount in Comparative Example 3 was about 2.6×10⁻⁷ [mbar·L/sec], which was higher than that in Example 4.

From the above, it was found that Example 4 has a relationship with the fact that outgas is less likely to be generated when the adhesive layer satisfies Formula (1b).

The materials of the adhesive layers of Example 5, Example 6, and Comparative Example 4 are the same (that is, the silicone-based adhesive).

In Example 5, Example 6, and Comparative Example 4, [C₃H₃O⁺_{50 s}] was less than 0.005, and ([CH₃Si⁺_{50 s}]+[C₃H₉Si⁺_{50 s}]) was 0.050 or more. That is, the material of the adhesive layer 13 of Example 5, Example 6, and Comparative Example 4 is determined to contain the Si-based adhesive.

The adhesive layers of Examples 5 and 6 satisfied the following Formula (1c). Therefore, an amount of outgassing from the volatile hydrocarbons (CxHy: m/z=45 to 100) generated in Examples 5 and 6 was about 3.4×10⁻⁷ [mbar·L/sec] or less.

$$[ {CH}_{3} {{Si}^{+}}_{2 s} ] / [ {CH}_{3} {{Si}^{+}}_{50 s} ] ) \leq 0.97 \qquad Formula ( 1 c )$$

In Formula (1c), [CH₃Si⁺_{2 s}] represents a normalized intensity of CH₃Si⁺ obtained by analyzing the first deep portion by TOF-SIMS. [CH₃Si⁺_{50 s}] represents a normalized intensity of CH₃Si⁺ obtained by analyzing the second deep portion by TOF-SIMS.

On the other hand, the adhesive layer of Comparative Example 4 did not satisfy Formula (1c). Therefore, an amount of outgas generated with respect to the volatile hydrocarbon (CxHy: m/z=45 to 100) in Comparative Example 4 was 1.0×10⁻⁵ [mbar·L/sec], which was higher than that in Examples 5 and 6.

From the above, in Examples 5 and 6, it was found that when the adhesive layer satisfies Formula (1c), outgas is less likely to be generated.

In Comparative Example 1, ([CNO⁻_{2 s}]/[CNO⁻_{50 s}]) was 1.50. That is, [CNO⁻_{2 s}] was higher than [CNO⁻_{50 s}]. The raw material monomer of Comparative Example 1 does not contain a functional group containing CNO. Therefore, it is presumed that the main reason why [CNO⁻_{2 s}] was higher than [CNO⁻_{50 s}] is that the functional group containing CNO was formed by thermal curing of the Ac-based adhesive 1.

In Example 4, ([CNO⁻_{2 s}]/[CNO⁻_{50 s}]) was 235.90. This is presumed to be mainly because the monomer of the Ac-based adhesive 2 does not contain a nitrogen atom.

The disclosure of Japanese Patent Application No. 2021-148629 filed on Sep. 13, 2021 is incorporated herein by reference in its entirety.

All documents, patent applications, and technical standards described in this specification are incorporated herein by reference to the same extent as if each document, patent application, and technical standard were specifically and individually indicated to be incorporated by reference.

1. A pellicle comprising:
a pellicle frame;
a pellicle film supported on one end surface of the pellicle frame; and
an adhesive layer provided on another end surface of the pellicle frame,
wherein at least one of an inner wall surface or an outer wall surface of a surface of the adhesive layer satisfies Formula (1) below:
$$( [ {A}_{2 s} ] / [ {A}_{50 s} ] ) \leq 0.97 \qquad Formula ( 1 )$$
wherein, in Formula (1):
[A_{2 s}] represents a normalized intensity of a partial structure contained in a main agent component of the adhesive layer obtained by analyzing a first deep portion having a first depth from a surface of the adhesive layer by time-of-flight secondary ion mass spectrometry using a primary ion gun in which an ion source is Bi₃⁺⁺ ions and an irradiation region is 100 μm×100 μm,
the first depth is formed by irradiating a 600 μm square area of the surface with a sputter ion gun that is an argon gas cluster ion beam having a beam voltage of 20 kV and a beam current of 20 nA for a total of 2 seconds,
[A_{50 s}] represents a normalized intensity of a partial structure contained in a main agent component of the adhesive layer obtained by analyzing a second deep portion where the depth is a second depth by time-of-flight secondary ion mass spectrometry, and
the second depth is formed by irradiating the area with the sputter ion gun for a total of 50 seconds.

2. The pellicle according to claim 1, wherein the partial structure contained in the main agent component is C₃H₃O⁺, C₇H₇⁺, or CH₃Si⁺.

3. The pellicle according to claim 1, wherein the at least one of the inner wall surface or the outer wall surface that satisfies Formula (1) satisfies Formula (2) below:
$$( [ {{CNO}^{-}}_{2 s} ] / [ {{CNO}^{-}}_{50 s} ] ) \geq 2. \qquad Formula ( 2 )$$
wherein, in Formula (2):
[CNO⁻_{2 s}] represents a normalized intensity of CNO⁻ obtained by analyzing the first deep portion by time-of-flight secondary ion mass spectrometry, and
[CNO⁻_{50 s}] represents a normalized intensity of CNO⁻ obtained by analyzing the second deep portion by time-of-flight secondary ion mass spectrometry.

4. The pellicle according to claim 1, wherein the at least one of the inner wall surface or the outer wall surface that satisfies Formula (1) satisfies Formula (3) below:
$$( [ {{CN}^{-}}_{2 s} ] / [ {{CN}^{-}}_{50 s} ] ) \geq 2. \qquad Formula ( 3 )$$
wherein, in Formula (3):
[CN⁻_{2 s}] represents a normalized intensity of CN⁻ obtained by analyzing the first deep portion by time-of-flight secondary ion mass spectrometry, and
[CN⁻_{50 s}] represents a normalized intensity of CN⁻ obtained by analyzing the second deep portion by time-of-flight secondary ion mass spectrometry.

5. The pellicle according to claim 3, wherein the at least one of the inner wall surface or the outer wall surface that satisfies Formula (1) satisfies Formula (4) below:
$$( [ {{CNO}^{-}}_{6 s} ] / [ {{CNO}^{-}}_{50 s} ] ) \geq 1.5 \qquad Formula ( 4 )$$
wherein, in Formula (4):
[CNO⁻_{6 s}] represents a normalized intensity of CNO⁻ obtained by analyzing a third deep portion having a third depth from the surface of the adhesive layer by time-of-flight secondary ion mass spectrometry using a primary ion gun in which an ion source is Bi₃⁺⁺ ions and an irradiation region is 100 μm×100 μm,
the third depth is formed by irradiating a 600 μm square area of the surface with a sputter ion gun that is an argon gas cluster ion beam having a beam voltage of 20 kV and a beam current of 20 nA for a total of 6 seconds, and
[CNO⁻_{50 s}] represents a normalized intensity of CNO⁻ obtained by analyzing the second deep portion by time-of-flight secondary ion mass spectrometry.

6. The pellicle according to claim 1, wherein the at least one of the inner wall surface or the outer wall surface that satisfies Formula (1) satisfies Formula (5) below:
$$( [ {{{C}_{3}}^{-}}_{2 s} ] / [ {{{C}_{3}}^{-}}_{50 s} ] ) \geq 1.1 \qquad Formula ( 5 )$$
wherein, in Formula (5):
[C₃⁻₂s] represents a normalized intensity of C₃⁻ obtained by analyzing the first deep portion by time-of-flight secondary ion mass spectrometry, and
[C₃⁻₅₀s] represents a normalized intensity of C₃⁻ obtained by analyzing the second deep portion by time-of-flight secondary ion mass spectrometry.

7. The pellicle according to claim 1, wherein:
a carbon atom concentration of the at least one of the inner wall surface or the outer wall surface is 35 at % or more, and
the carbon atom concentration indicates a ratio (%) of integrated intensity of peak components derived from carbon atoms to integrated intensity of peak components of all components in a narrow spectrum of X-ray photoelectron spectroscopy of the at least one of the inner wall surface or the outer wall surface.

8. The pellicle according to claim 1, wherein:
a nitrogen atom concentration of the at least one of the inner wall surface or the outer wall surface is 1.0 at % or more, and
the nitrogen atom concentration indicates a ratio (%) of integrated intensity of peak components derived from nitrogen atoms to integrated intensity of peak components of all components in a narrow spectrum of X-ray photoelectron spectroscopy of the at least one of the inner wall surface or the outer wall surface.

9. An exposure original plate comprising: an original plate having a pattern; and the pellicle according to claim 1 attached to a surface of the original plate on a side having the pattern.

10. An exposure device comprising: a light source that emits exposure light; the exposure original plate according to claim 9; and an optical system that guides the exposure light emitted from the light source to the exposure original plate, wherein the exposure original plate is disposed such that the exposure light emitted from the light source passes through the pellicle film and is irradiated onto the original plate.

11. A method of manufacturing the pellicle according to claim 1, the method comprising:
forming the adhesive layer by subjecting at least one of an inner wall surface or an outer wall surface of a surface of an adhesive layer precursor to a plasma nitriding treatment or an extreme ultraviolet irradiation treatment, the adhesive layer precursor being formed by applying a coating composition to the other end surface of the pellicle frame and heating the coating composition.

12. The method of manufacturing the pellicle according to claim 11, further comprising:
disposing the pellicle coated with the coating composition under a pressure of 5×10⁻⁴ Pa or less for 10 minutes or more before performing the plasma nitriding treatment, and then disposing the pellicle under an inert gas atmosphere having a partial pressure of H₂O of 100 ppm or less and an atmospheric pressure of 90 kPa or more for 5 seconds or more,
wherein the adhesive layer contains an acrylic adhesive.
